(19) United States
(12) Patent Application Publication
(10) Pub. No.: US 2025/0180989 A1
(43) Pub. Date: Jun. 5, 2025

(54) COMPOSITION FOR PRETREATMENT

(71) Applicant: NISSAN CHEMICAL CORPORATION, Tokyo (JP)

(72) Inventor: Satoshi KAMIBAYASHI, Toyama-shi (JP)

(73) Assignee: NISSAN CHEMICAL CORPORATION, Tokyo (JP)

(21) Appl. No.: 18/842,927

(22) PCT Filed: Feb. 21, 2023
(86) PCT No.: PCT/JP2023/006328

§ 371 Date: Aug. 30, 2024

(30) Foreign Application Priority Data
Mar. 9, 2022 (JP) 2022-036520

(51) Int. Cl. G03F 7/004; G03F 7/039; G03F 7/40; H01L 21/311

(52) U.S. Cl. CPC G03F 7/0048; G03F 7/039; G03F 7/40; H01L 21/31111; H01L 21/31138; H01L 21/31144

(57) ABSTRACT

A composition for pretreatment to be applied on a semiconductor substrate before a protective film is formed on the semiconductor substrate using a composition for forming a protective film, the composition for pretreatment including: at least one compound (A) selected from a compound having an aromatic ring and an aromatic hydroxy group, an organic reducing agent, and a chelating agent; and a solvent (B).

### TECHNICAL FIELD

The present invention relates to a composition for pretreatment for forming a protective film having excellent resistance particularly to a wet etching solution for semiconductors in a lithography process in semiconductor production. The invention also relates to a method for producing a resist pattern-attached substrate using the composition for pretreatment, and a method for producing a semiconductor device.

### BACKGROUND ART

In semiconductor production, a lithography process for forming a resist pattern having a desired shape by providing a resist underlayer film between a substrate and a resist film formed thereon, is widely known. The substrate is processed after the resist pattern is formed, and dry etching is mainly used as the process; however, wet etching may be used depending on the substrate type. Patent Literature 1 discloses a resist underlayer film material having resistance to alkaline hydrogen peroxide water.

### CITATION LIST

### Patent Literature

Patent Literature 1: JP 2018-173520 A

### SUMMARY OF INVENTION

### Technical Problem

When a protective film for a semiconductor substrate is formed using a composition for forming a protective film, and processing of a base substrate is performed by wet etching using the protective film as an etching mask, the protective film is required to have a satisfactory masking function (that is, a masked portion can protect the substrate) with respect to a wet etching solution for semiconductors. Furthermore, in the production process for semiconductor devices, when the amount of a sublimate generated from the protective film is large, problems such as contamination of the top plate and the inside of pipes of a baker used at the time of firing occur.

The present invention has been made in view of the above-described circumstances, and an object of the present invention is to provide a composition for pretreatment capable of forming a protective film having excellent resistance to a wet etching solution for semiconductors while suppressing the amount of generation of a sublimate. Another object of the present invention is to provide a method for producing a resist pattern-attached substrate using the composition for pretreatment, and a method for producing a semiconductor device.

### Solution to Problem

The inventors of the present invention conducted intensive studies to solve the above-described problems, and as a result, the inventors have found that the above-described problems can be solved by using a composition for pretreatment containing a specific compound, thus completing the present invention.

That is, the present invention includes the following aspects.

[1] A composition for pretreatment to be applied on a semiconductor substrate before a protective film is formed on the semiconductor substrate using a composition for forming a protective film,
the composition for pretreatment including: at least one compound (A) selected from a compound having an aromatic ring and an aromatic hydroxy group, an organic reducing agent, and a chelating agent; and a solvent (B).

[2] The composition for pretreatment according to [1], wherein the compound having an aromatic ring and an aromatic hydroxy group is at least one selected from tannic acid and a compound represented by the following Formula (1):

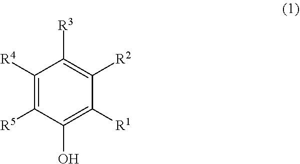

in Formula (1), R¹ to R⁵ each independently represent a hydrogen atom, a hydroxy group, an alkoxy group having 1 to 3 carbon atoms, a carboxy group, an alkyloxycarbonyl group, or a carboxyl hydrocarbon group;
provided that at least one of R¹ to R⁵ represents a hydroxy group, an alkoxy group having 1 to 3 carbon atoms, a carboxy group, an alkyloxycarbonyl group, or a carboxy hydrocarbon group.

[3] The composition for pretreatment according to [1] or [2], wherein the organic reducing agent is at least one selected from ascorbic acid and an ascorbic acid derivative.

[4] The composition for pretreatment according to any one of [1] to [3], wherein
the chelating agent has a first partial structure selected from a pyridine ring, an aromatic hydroxy group, and an acid group, and a second partial structure selected from a pyridine ring, an aromatic hydroxy group, and an acid group, or
the chelating agent has a β-diketone structure (—C(═O)—CH₂—C(═O)—).

[5] The composition for pretreatment according to [4], wherein
the acid group in the first partial structure is either a carboxyl group (—COOH) directly linked to an aromatic ring, or a dihydroxyboryl group (—B(OH)₂) directly linked to an aromatic ring, and
the acid group in the second partial structure is either a carboxyl group (—COOH) directly linked to an aromatic ring, or a dihydroxyboryl group (—B(OH)₂) directly linked to an aromatic ring.

[6] The composition for pretreatment according to any one of [1] to [5], wherein the solvent (B) includes at least one selected from water and a glycol-based solvent.

[7] The composition for pretreatment according to any one of [1] to [6], wherein
a content of the compound (A) is 0.1% by mass to 10% by mass, and
a content of the solvent (B) is 90% by mass to 99.9% by mass.

[8] A method for producing a resist pattern-attached substrate used in semiconductor production, the method including:
a step of applying the composition for pretreatment according to any one of [1] to [7] on a semiconductor substrate;
a step of applying a composition for forming a protective film on the semiconductor substrate on which the composition for pretreatment has been applied, and baking the composition for forming a protective film to form a protective film; and
a step of forming a resist film directly on the protective film or with another layer interposed therebetween, and then exposing and developing the resist film to form a resist pattern.

[9] A method for producing a semiconductor device, the method including steps of: applying the composition for pretreatment according to any one of [1] to [7] on a semiconductor substrate having an inorganic film formed on a surface thereof; forming a protective film on the semiconductor substrate on which the composition for pretreatment has been applied, using a composition for forming a protective film; forming a resist pattern directly on the protective film or with another layer interposed therebetween; subjecting the protective film to dry etching using the resist pattern as a mask to expose a surface of the inorganic film; and subjecting the inorganic film to wet etching by using the protective film after the dry etching as a mask and using a wet etching solution for semiconductors.

### Advantageous Effects of Invention

According to the present invention, a composition for pretreatment capable of forming a protective film having excellent resistance to a wet etching solution for semiconductors while suppressing the amount of generation of a sublimate, can be provided. Furthermore, according to the present invention, a method for producing a resist pattern-attached substrate using the composition for pretreatment and a method for producing a semiconductor device can be provided.

### DESCRIPTION OF EMBODIMENTS

### (Composition for Pretreatment)

The composition for pretreatment of the present invention contains at least one compound (A) selected from a compound having an aromatic ring and an aromatic hydroxy group, an organic reducing agent, and a chelating agent, and a solvent (B).

The composition for pretreatment is a composition that is applied on a semiconductor substrate before a protective film is formed on the semiconductor substrate using a composition for forming a protective film.

At least one compound (A) selected from a compound having an aromatic ring and an aromatic hydroxy group, an organic reducing agent, and a chelating agent may be referred to as “specific compound (A)”.

The present inventors conducted extensive studies for forming a protective film having excellent resistance to a wet etching solution for semiconductors. Then, the present inventors found that when a specific compound (A) is contained in a composition for forming a protective film, a protective film having excellent resistance to a wet etching solution for semiconductors can be formed.

However, the present inventors found that when a specific compound (A) is contained in a composition for forming a protective film, the amount of a sublimate generated from the protective film increases.

Thus, as a result of conducting further studies, the present inventors found that a protective film having excellent resistance to a wet etching solution for semiconductors while suppressing the amount of generation of a sublimate can be formed, not by allowing a composition for forming a protective film to contain a specific compound (A), but by applying a composition for pretreatment containing a specific compound (A) on a semiconductor substrate before forming a protective film on the semiconductor substrate using a composition for forming a protective film, thus completing the present invention.

### <Specific Compound (A)>

The specific compound (A) is at least one compound selected from a compound having an aromatic ring and an aromatic hydroxy group, an organic reducing agent, and a chelating agent.

The present inventors believe that the specific compound (A) can impart resistance to a wet etching solution for semiconductors to a protective film by closely adhering to a semiconductor substrate (or a metal film) to form a film and also acting on a resin in a composition for forming a protective film.

### <<Compound Having Aromatic Ring and Aromatic Hydroxy Group>>

The compound having an aromatic ring and an aromatic hydroxy group (hereinafter, may be referred to as “compound (A-1)”) is not particularly limited as long as the effect of the present invention can be exhibited.

The aromatic ring in compound (A-1) may be an aromatic hydrocarbon ring or may be an aromatic heterocyclic ring; however, the aromatic ring is preferably an aromatic hydrocarbon ring. The aromatic hydrocarbon ring may be a monocyclic ring or may be a fused ring. Examples of the aromatic hydrocarbon ring include a benzene ring, a naphthalene ring, and an anthracene ring.

The aromatic hydroxy group in the compound (A-1) is not particularly limited as long as it is a hydroxy group directly bonded to an aromatic ring. The aromatic ring to which the hydroxy group is directly bonded may be an aromatic hydrocarbon ring or may be an aromatic heterocyclic ring; however, the aromatic ring is preferably an aromatic hydrocarbon ring. The aromatic hydrocarbon ring may be a monocyclic ring or may be a fused ring. Examples of the aromatic hydrocarbon ring include a benzene ring, a naphthalene ring, and an anthracene ring.

The number of aromatic rings in the compound (A-1) is not particularly limited.

The number of aromatic hydroxy groups in the compound (A-1) is not particularly limited.

As the compound (A-1), tannic acid and a compound represented by the following Formula (1) are preferable from the viewpoint of suitably obtaining the effect of the present invention.

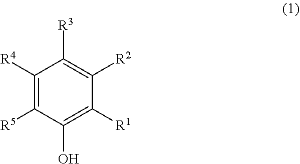

(in Formula (1), R¹ to R⁵ each independently represent a hydrogen atom, a hydroxy group, an alkoxy group having 1 to 3 carbon atoms, a carboxy group, an alkyloxycarbonyl group, or a carboxyl hydrocarbon group;
provided that at least one of R¹ to R⁵ represents a hydroxy group, an alkoxy group having 1 to 3 carbon atoms, a carboxy group, an alkyloxycarbonyl group, or a carboxy hydrocarbon group.)

The number of carbon atoms of the alkyloxycarbonyl group may be, for example, 2 to 6. Examples of the alkyloxycarbonyl group include a methyloxycarbonyl group, an ethyloxycarbonyl group, a propyloxycarbonyl group, and a butyloxycarbonyl group.

The carboxy hydrocarbon group is a hydrocarbon group substituted with a carboxy group.

Examples of the carboxy hydrocarbon group include an organic group represented by the following Formula (1-1).

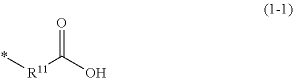

(In Formula (1-1), R¹¹ represents a divalent hydrocarbon group having 1 to 5 carbon atoms.)

The divalent hydrocarbon group having 1 to 5 carbon atoms may be a saturated hydrocarbon group or may be an unsaturated hydrocarbon group. In the case of an unsaturated hydrocarbon group, examples of the unsaturated bond include a carbon-carbon double bond. The number of unsaturated bonds in the unsaturated hydrocarbon group may be one or may be two.

Examples of the carboxy hydrocarbon group include a carboxymethyl group, a carboxyethyl group, a carboxypropyl group, a carboxybutyl group, a carboxyethenyl group, a carboxypropenyl group, and a carboxybutenyl group.

Specific examples of the compound (A-1) include the following compounds.

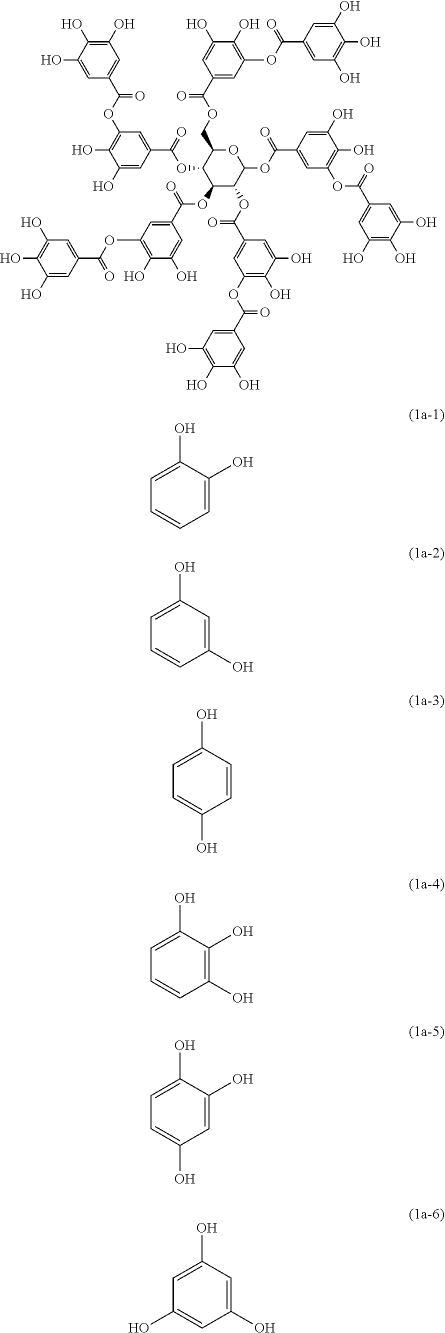

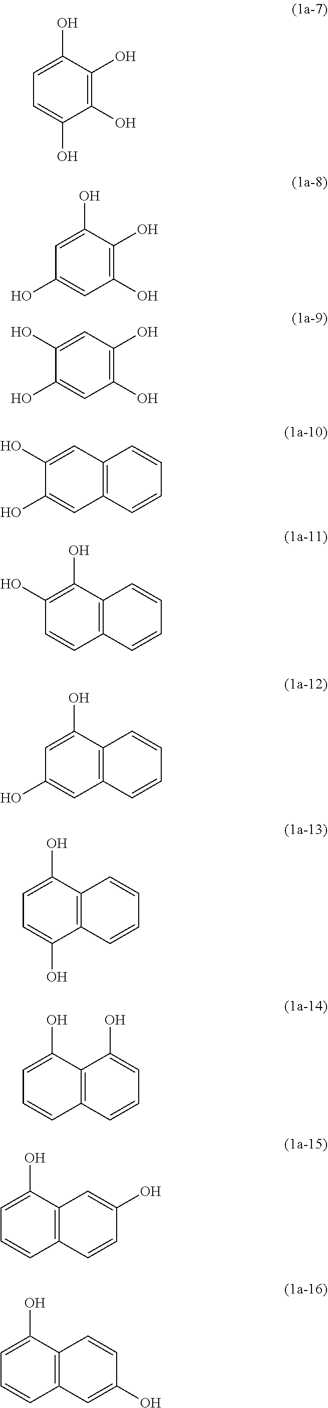

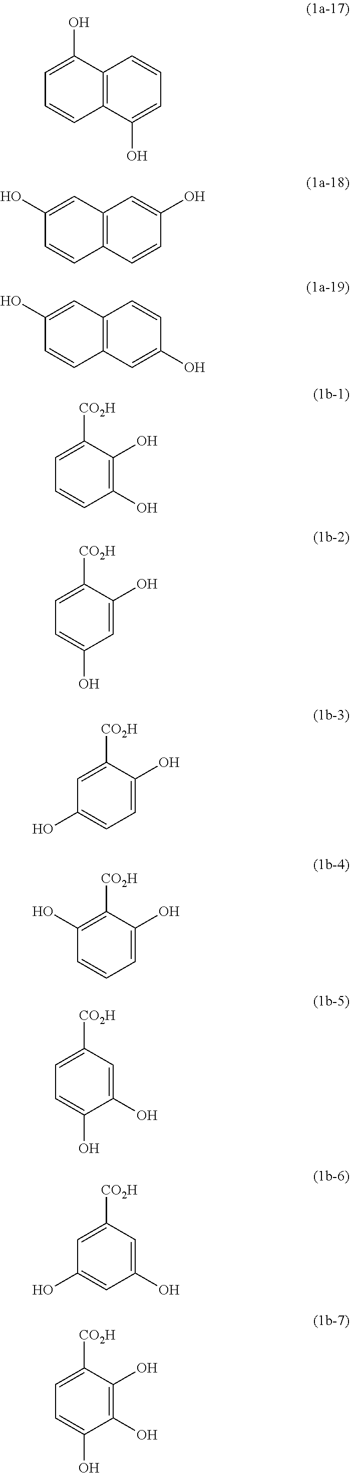

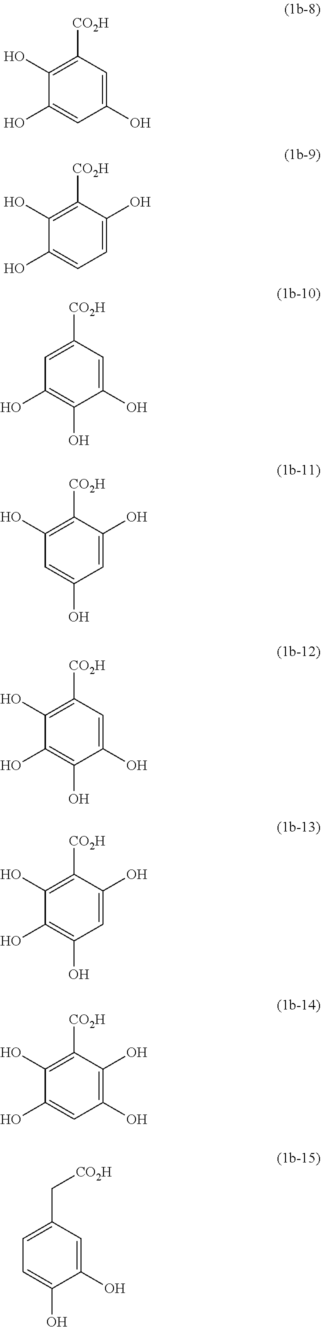

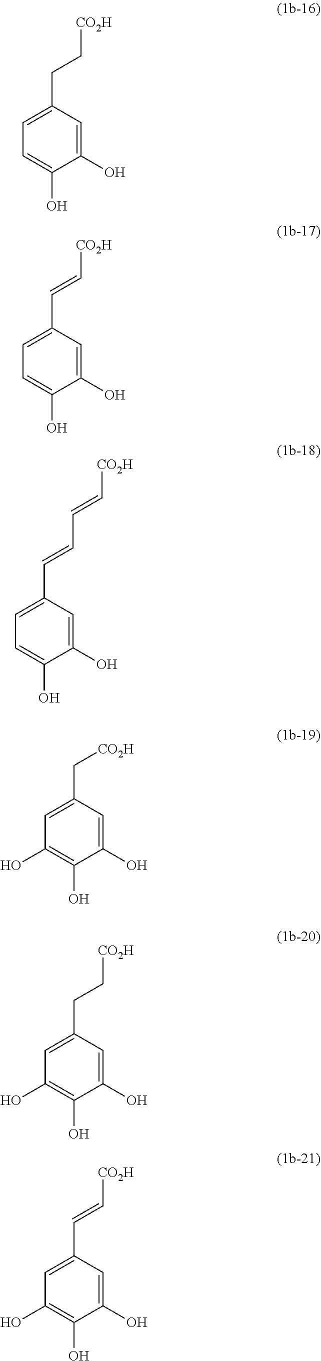 [SMILES: O=C(O)CCc1ccc(O)c(O)c1 ; O=C(O)/C=C/c1ccc(O)c(O)c1 ; O=C(O)/C=C/C=C/c1ccc(O)c(O)c1 ; O=C(O)Cc1cc(O)c(O)c(O)c1 ; O=C(O)CCc1cc(O)c(O)c(O)c1 ; O=C(O)/C=C/c1cc(O)c(O)c(O)c1]

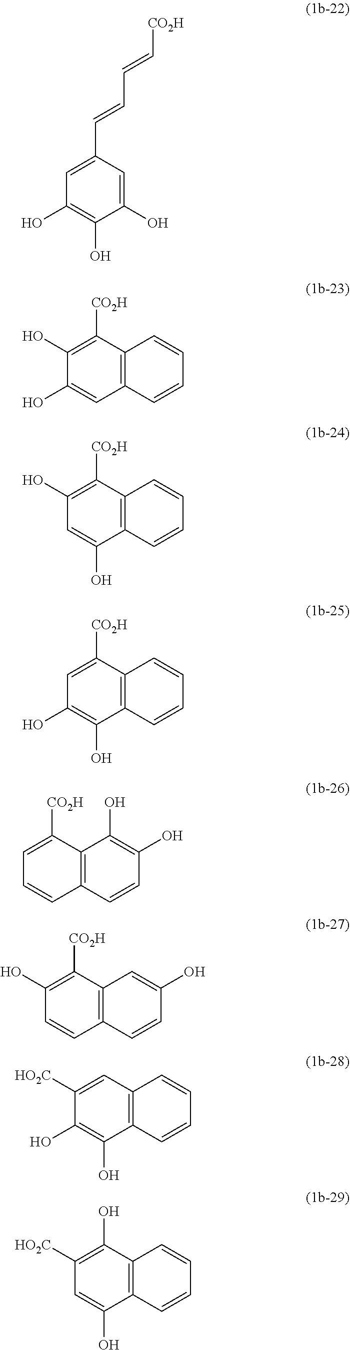

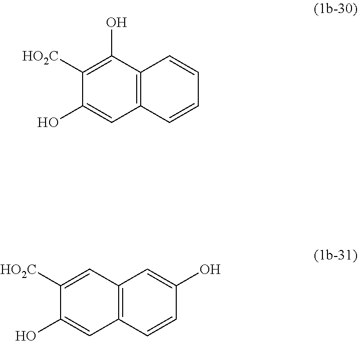 [SMILES: O=C(O)c1c(O)cc2ccccc2c1O ; O=C(O)c1cc2cc(O)ccc2cc1O]

### <<Organic Reducing Agent>>

The organic reducing agent is not particularly limited as long as the effect of the present invention can be exhibited, and examples thereof include a carboxylic acid having reducibility, an ascorbic acid, and a monosaccharide.

Examples of the carboxylic acid having reducibility include formic acid, oxalic acid, succinic acid, lactic acid, malic acid, citric acid, and pyruvic acid.

Examples of the ascorbic acid include ascorbic acid, isoascorbic acid, an ascorbic acid derivative, and an isoascorbic acid derivative.

Examples of the ascorbic acid derivative include ascorbic acid, an ascorbic acid ester, isoascorbic acid, and an isoascorbic acid ester.

Examples of the ascorbic acid ester include ascorbyl stearate, ascorbyl palmitate, ascorbyl dipalmitate, ascorbyl tetrahexyldecanoate, and ascorbyl glucoside.

Examples of the isoascorbic acid ester include isoascorbyl stearate, isoascorbyl palmitate, isoascorbyl dipalmitate, isoascorbyl tetrahexyldecanoate, and isoascorbic acid glucoside.

Among the ascorbic acid esters and isoascorbic acid esters, for example, in the case of ascorbic acid esters containing alkali metals and alkaline earth metals, such as sodium ascorbate, sodium ascorbate sulfate, sodium ascorbate phosphate, and magnesium ascorbate phosphate, these alkali metals and alkaline earth metals may cause deterioration of electrical characteristics on a semiconductor substrate, and therefore, it is not preferable to use ascorbic acid esters containing the alkali metals and the like.

Examples of the monosaccharide include a reducing pentose and a reducing hexose.

Examples of the reducing pentose include arabinose, xylose, and ribose.

Examples of the reducing hexose include glucose, mannose, fructose, and galactose.

### <<Chelating Agent>>

The chelating agent is not particularly limited as long as the effect of the present invention can be exhibited; however, it is preferable that the chelating agent has the following first partial structure and second partial structure, or has a β-diketone structure (—C(═O)—CH₂—C(═O)—).

First partial structure: a partial structure selected from a pyridine ring, an aromatic hydroxy group, and an acid group

Second partial structure: a partial structure selected from a pyridine ring, an aromatic hydroxy group, and an acid group

For example, the first partial structure and the second partial structure together exert a chelating ability on a metal.

The β-diketone structure (—C(═O)—CH₂—C(═O)—) by itself exerts a chelating ability on metals.

Examples of the acid group in the first partial structure and the second partial structure include a carboxyl group (—COOH) directly linked to an aromatic ring and a dihydroxyboryl group (—B(OH)₂) directly linked to an aromatic ring.

The aromatic ring may be, for example, an aromatic hydrocarbon ring or may be an aromatic heterocyclic ring.

The aromatic hydrocarbon ring may be a monocyclic ring or may be a fused ring. Examples of the aromatic hydrocarbon ring include a benzene ring, a naphthalene ring, and an anthracene ring.

The aromatic heterocyclic ring may be a monocyclic ring or may be a fused ring. Examples of a heteroatom in the aromatic heterocyclic ring include a nitrogen atom, an oxygen atom, and a sulfur atom. When the aromatic heterocyclic ring is a monocyclic ring, the aromatic heterocyclic ring may be, for example, a 5-membered ring or may be a 6-membered ring. Examples of the aromatic heterocyclic ring include a furan ring, a thiophene ring, an imidazole ring, a pyridine ring, a piperidine ring, and a quinoline ring.

Specific examples of the chelating agent include the following compounds.

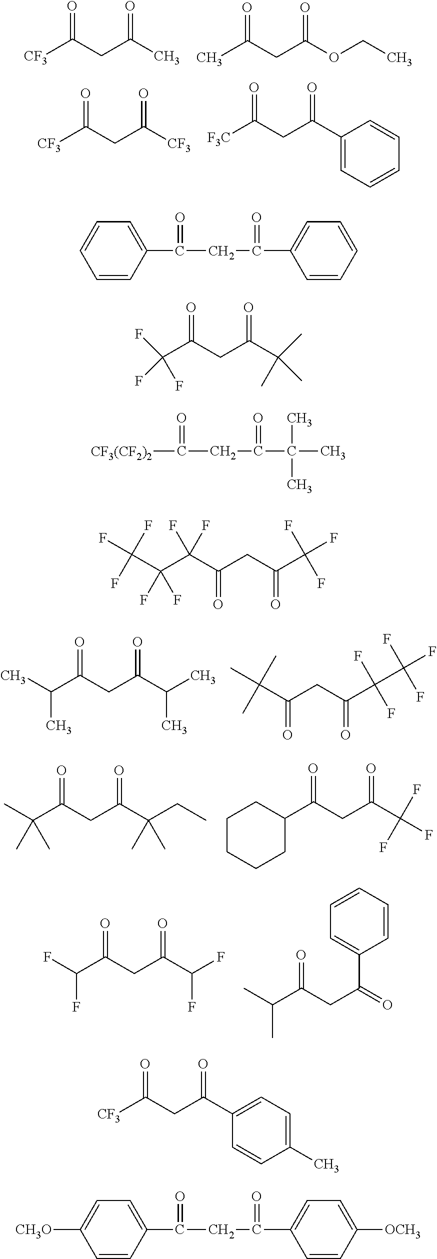

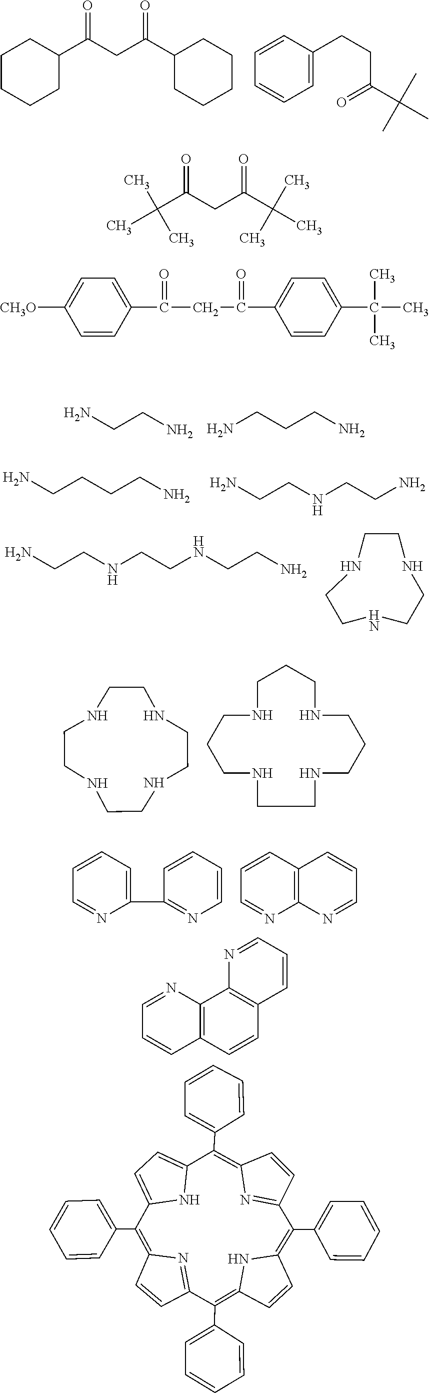

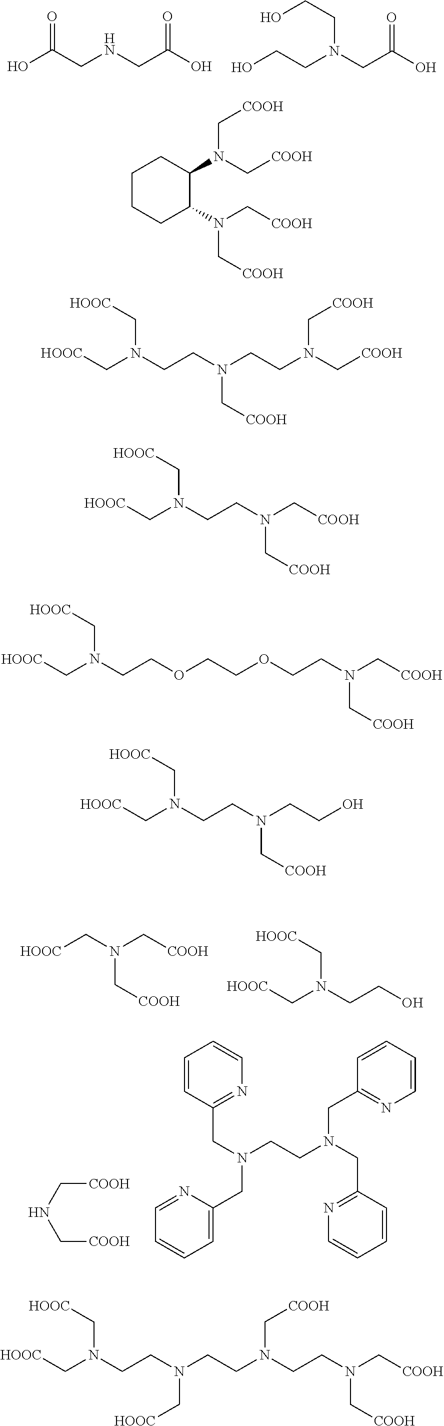

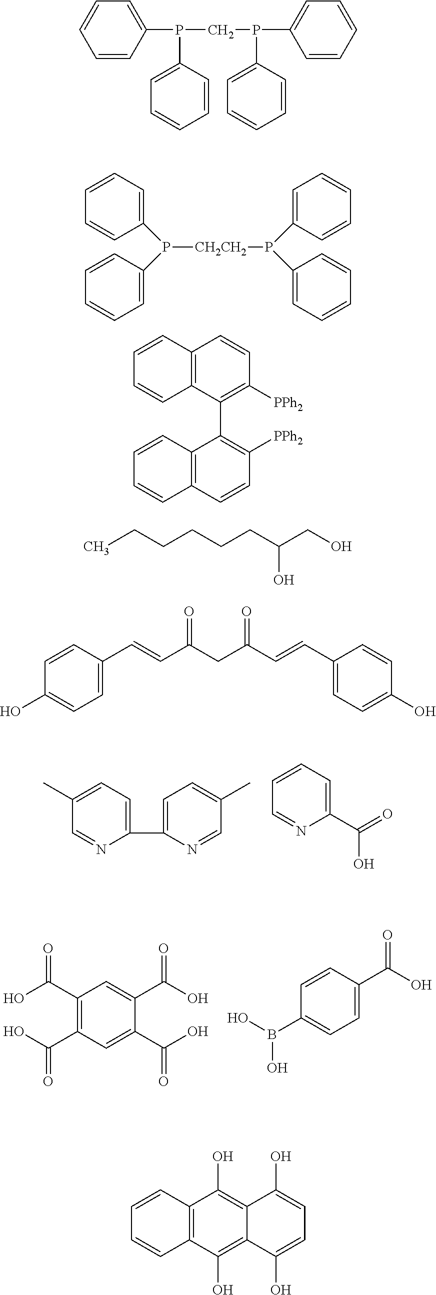

The molecular weight of the specific compound (A) is not particularly limited, but is preferably 500 or less, and preferably 300 or less, except for tannic acid.

The content of the specific compound (A) in the composition for pretreatment is not particularly limited; however, the content is preferably 0.1% by mass to 10% by mass, more preferably 0.1% by mass to 7% by mass, and particularly preferably 0.5% by mass to 5% by mass.

### <Solvent (B)>

The solvent (B) used in the composition for pretreatment is not particularly limited as long as it is a solvent capable of uniformly dissolving the contained components; however, water and a glycol-based solvent are preferable.

Examples of the glycol-based solvent include a solvent represented by R—(O-A)n-OR. In the formula, A represents an alkylene group having 2 to 10 carbon atoms, and preferably 2 to 3 carbon atoms; n represents an integer of 1 to 4, and preferably an integer of 1 to 3; and R's each independently represent a hydrogen atom, an alkyl group having 1 to 6 carbon atoms (preferably an alkyl group having 1 to 4 carbon atoms), or an acyl group having 2 to 4 carbon atoms (preferably an acyl group having 2 or 3 carbon atoms).

As the glycol-based solvent, diethylene glycol monoalkyl ether, diethylene glycol dialkyl ether, ethylene glycol monoalkyl ether, ethylene glycol monoalkyl ether acetate, diethylene glycol monoalkyl ether acetate, propylene glycol monoalkyl ether acetate, propylene glycol monoalkyl ether, dipropylene glycol monoalkyl ether, dipropylene glycol dialkyl ether, propylene glycol monoalkyl ether propionate, and triethylene glycol dialkyl ether are preferable.

Examples of the diethylene glycol monoalkyl ether include diethylene glycol monomethyl ether and diethylene glycol monoethyl ether.

Examples of the diethylene glycol dialkyl ether include diethylene glycol dimethyl ether, diethylene glycol diethyl ether, and diethylene glycol methyl ethyl ether.

Examples of the ethylene glycol monoalkyl ether include ethylene glycol monomethyl ether, ethylene glycol monoethyl ether, and ethylene glycol monobutyl ether.

Examples of the ethylene glycol monoalkyl ether acetate include ethylene glycol monomethyl ether acetate, ethylene glycol monoethyl ether acetate, and ethylene glycol monobutyl ether acetate.

Examples of the diethylene glycol monoalkyl ether acetate include diethylene glycol monomethyl ether acetate, diethylene glycol monoethyl ether acetate, and diethylene glycol monobutyl ether acetate.

Examples of the propylene glycol monoalkyl ether acetate include propylene glycol monomethyl ether acetate, propylene glycol monoethyl ether acetate, propylene glycol monopropyl ether acetate, and propylene glycol monobutyl ether acetate.

Examples of the propylene glycol monoalkyl ether include propylene glycol monomethyl ether, propylene glycol monoethyl ether, propylene glycol monopropyl ether, and propylene glycol monobutyl ether.

Examples of the dipropylene glycol monoalkyl ether include dipropylene glycol monomethyl ether and dipropylene glycol butyl ether.

Examples of the dipropylene glycol dialkyl ether include dipropylene glycol dimethyl ether.

Examples of the propylene glycol monoalkyl ether propionate include propylene glycol monomethyl ether propionate, propylene glycol monoethyl ether propionate, propylene glycol monopropyl ether propionate, and propylene glycol monobutyl ether propionate.

Examples of the triethylene glycol dialkyl ether include triethylene glycol dimethyl ether.

The content of the solvent (B) in the composition for pretreatment is not particularly limited; however, the content is preferably 90% by mass to 99.9% by mass, more preferably 93% by mass to 99.9% by mass, and particularly preferably 95% by mass to 99.5% by mass.

### <Other Components>

In the composition for pretreatment, a surfactant can be further added in order to prevent the generation of pinholes, striations, and the like and to further improve the coating property against surface unevenness. Examples of the surfactant include nonionic surfactants, such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octyl phenol ether and polyoxyethylene nonyl phenol ether; polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, EF352 (manufactured by TOCHEM PRODUCTS Co., Ltd., trade name), MEGAFACE F171, F173, R-30, and R-40 (manufactured by DIC Corporation, trade name), FLUORAD FC430 and FC431 (manufactured by Sumitomo 3M, Ltd., trade name), ASAHIGUARD AG710, and SURFLON S-382, SC101, SC102, SC103, SC104, SC105, and SC106 (manufactured by Asahi Glass Co., Ltd., trade name); and organosiloxane polymer KP341 (manufactured by Shin-Etsu Chemical Co., Ltd.). The blending amount of these surfactants is usually 2.0% by mass or less, and preferably 1.0% by mass or less, with respect to components other than the solvent of the composition for pretreatment. These surfactants may be added alone, or may be added in combination of two or more kinds thereof.

The components of the composition for pretreatment excluding the solvent are, for example, 0.1% by mass to 5% by mass.

### <Composition for Forming Protective Film>

The composition for forming a protective film is a composition for forming a protective film.

The protective film is a protective film that protects an inorganic film of a semiconductor substrate having the inorganic film formed on the surface thereof, from wet etching.

The composition for forming a protective film is not particularly limited, and examples thereof include a composition for forming a protective film or a composition for forming a resist underlayer film in the production of conventionally known semiconductor elements.

Examples of the composition for forming a protective film include the following compositions.
Protective film-forming composition described in WO 2017/191767 A
Protective film-forming composition described in WO 2018/052130 A
Protective film-forming composition described in WO 2018/203464 A
Protective film-forming composition described in WO 2019/124474 A
Protective film-forming composition described in WO 2019/124475 A
Protective film-forming composition described in WO 2020/090950 A
Protective film-forming composition described in WO 2020/153278 A

The contents of these publications are incorporated herein by reference to the same extent as if fully set forth.

Examples of the composition for forming a resist underlayer film include the following compositions.
Composition for forming a resist underlayer film described in WO 2018/203540 A
Composition for forming resist underlayer film described in WO 2020/026834 A

The contents of these publications are incorporated herein by reference to the same extent as if fully set forth.

Hereinafter, an embodiment of the composition for forming a protective film will be described.

The composition for forming a protective film contains at least a compound or a resin (polymer) and a solvent.

### <<Compound or Resin (Polymer)>>

### First Embodiment

A first embodiment is a resin having a repeating structural unit containing at least one —C(═O)—O— group in a main chain and a repeating structural unit containing at least one hydroxy group in a side chain, or having a repeating structural unit containing at least one —C(═O)—O— group in a main chain and at least one hydroxy group in a side chain. Preferably, these repeating structural units do not have an organic group containing an epoxy ring or an oxetane ring.

The resin of the first embodiment is, for example, a copolymer having a repeating structural unit represented by the following Formula (1-1) and a repeating structural unit represented by the following Formula (1-2):

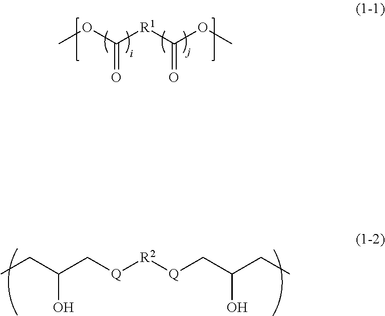

(wherein R¹ and R² each independently represent a divalent organic group containing a linear, branched, or cyclic functional group having 2 to 20 carbon atoms, the organic group may have at least one sulfur atom, nitrogen atom or oxygen atom; i and j each independently represent 0 or 1; and two Qs each represent a single bond, an —O— group, or a —C(═O)—O— group, provided that when both i and j are 0, at least one Q of the two Qs represents a —C(═O)—O— group.)

With regard to the resin of the first embodiment, preferably, in the repeating structural unit represented by Formula (1-1), R¹ represents a linear, branched, or cyclic divalent hydrocarbon group having 2 to 20 carbon atoms, represents a linear, branched, or cyclic divalent organic group having 2 to 20 carbon atoms and having at least one sulfur atom or oxygen atom, or represents a divalent organic group containing at least one of an aromatic ring having 6 to 20 carbon atoms or a heterocyclic ring having 3 to 12 carbon atoms, the heterocyclic ring having at least one sulfur atom or oxygen atom.

With regard to the resin of the first embodiment, preferably, in the repeating structural unit represented by Formula (1-2), R2 represents a linear, branched, or cyclic divalent hydrocarbon group having 2 to 20 carbon atoms, or represents a divalent organic group containing at least one of an aromatic ring having 6 to 20 carbon atoms or a heterocyclic ring having 3 to 12 carbon atoms, the heterocyclic ring having at least one sulfur atom or oxygen atom.

Examples of the aromatic ring include a benzene ring, a naphthalene ring, an anthracene ring, a phenanthrene ring, a naphthacene ring, a triphenylene ring, a pyrene ring, and a chrysene ring, and a benzene ring and a naphthalene ring are preferable.

Examples of the heterocyclic ring include a triazine ring, a cyanuric ring, a pyrimidine ring, an imidazole ring, and a carbazole ring.

As the resin of the first embodiment, a commercially available product or a copolymer synthesized from commercially available products by a known method can be used.

As the resin of the first embodiment, a copolymer of at least one compound represented by the following Formula (A) and at least one diepoxy compound represented by the following Formula (B) can be used:

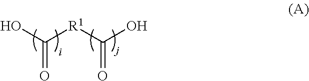

(in the formula, R¹, i, and j have the same meanings as R¹, i, and j in Formula (1-1), respectively, and

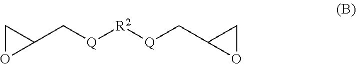

in the formula, R² and Q have the same meanings as R² and Q in Formula (1-2), respectively.)

That is, a copolymer having a repeating structural unit represented by the Formula (1-1) and a repeating structural unit represented by the Formula (1-2) is obtained by dissolving at least one compound represented by Formula (A) and at least one diepoxy compound represented by Formula (B) in an organic solvent so as to have an appropriate molar ratio, and polymerizing the compounds, if necessary, in the presence of a catalyst.

The compound represented by the Formula (A) is not particularly limited; however, examples thereof include compounds represented by the following formulas.

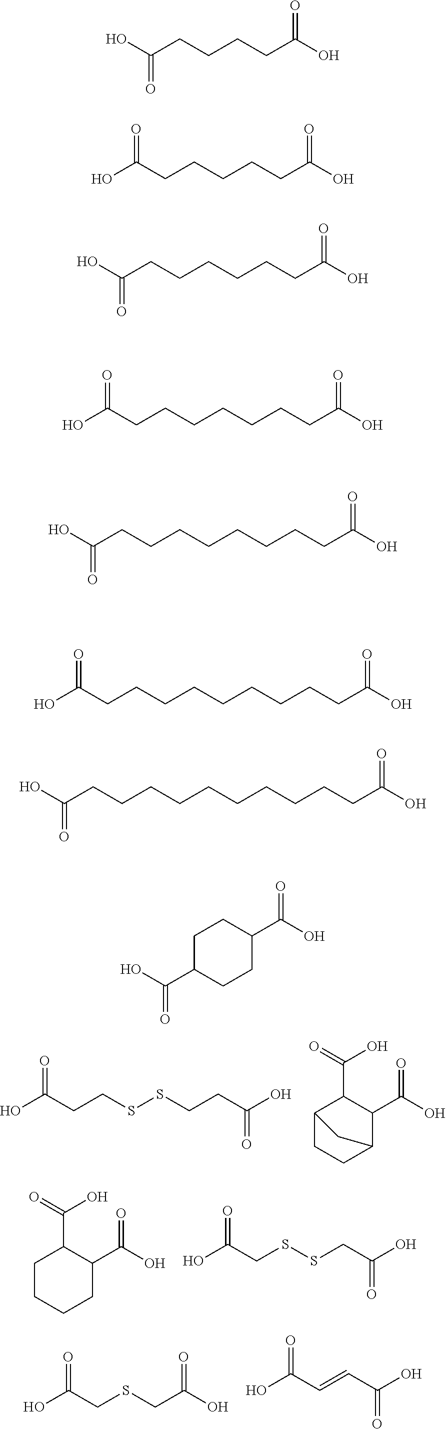

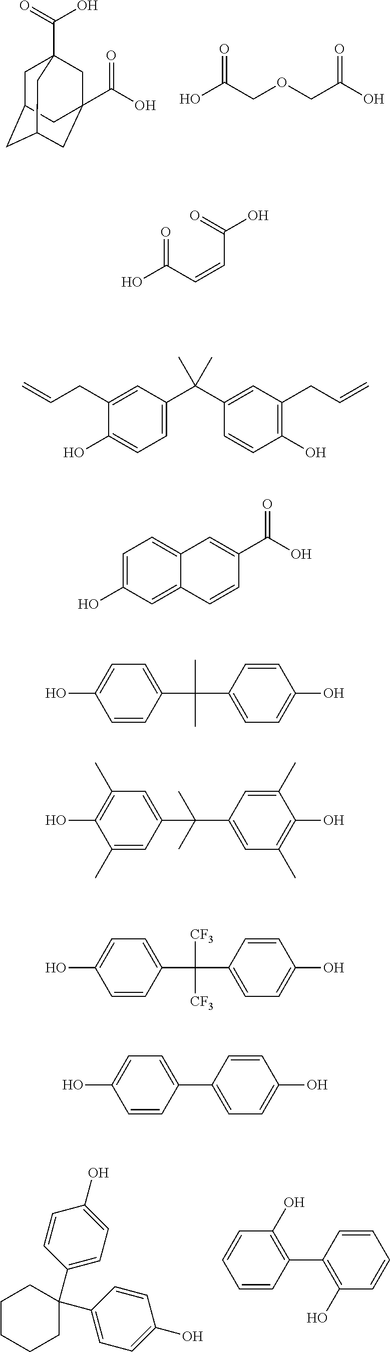

The diepoxy compound represented by the Formula (B) is not particularly limited; however, examples thereof include the following diepoxy compounds.

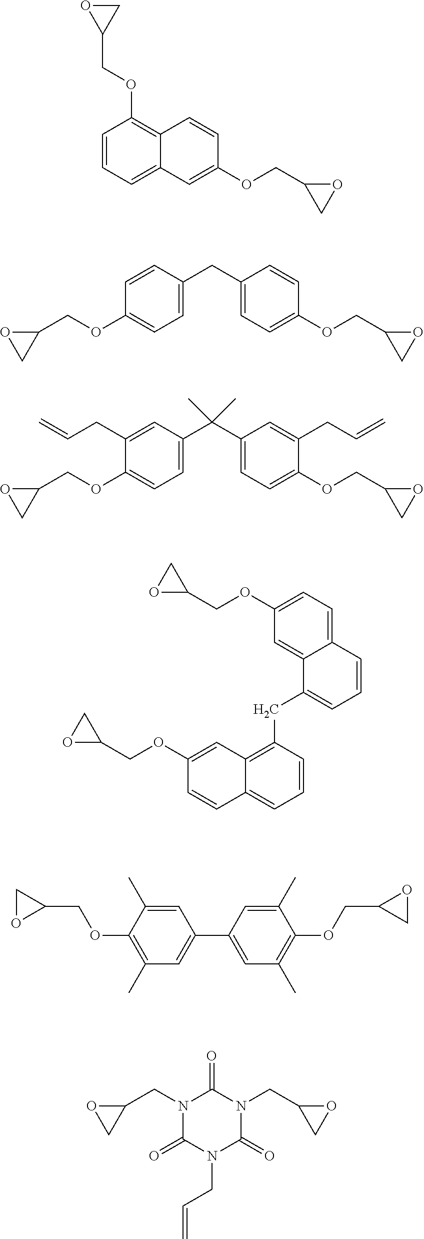 [SMILES: c1cc(OCC2CO2)c2ccc(OCC3CO3)cc2c1 ; c1cc(OCC2CO2)ccc1Cc1ccc(OCC2CO2)cc1 ; C=CCc1cc(C(C)(C)c2ccc(OCC3CO3)c(CC=C)c2)ccc1OCC1CO1 ; c1cc(Cc2cccc3ccc(OCC4CO4)cc23)c2cc(OCC3CO3)ccc2c1 ; Cc1cc(-c2cc(C)c(OCC3CO3)c(C)c2)cc(C)c1OCC1CO1 ; C=CCn1c(=O)n(CC2CO2)c(=O)n(CC2CO2)c1=O]

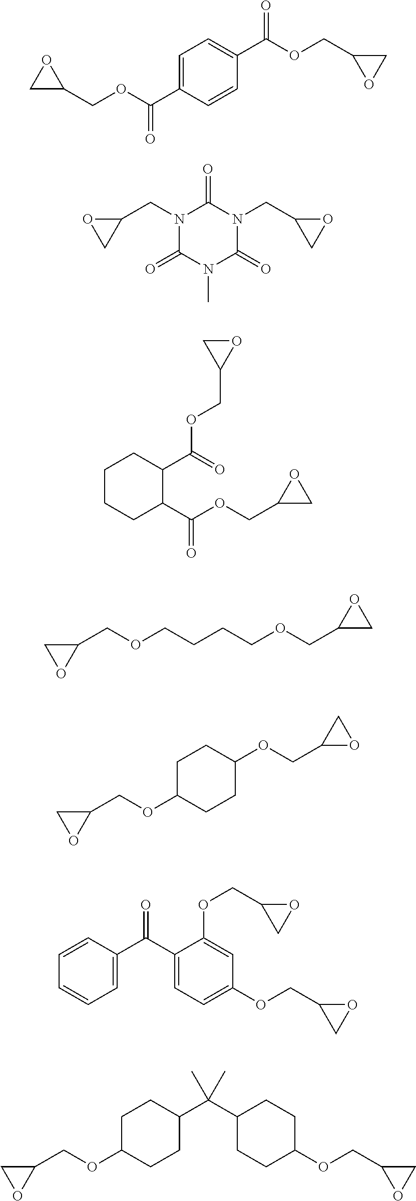

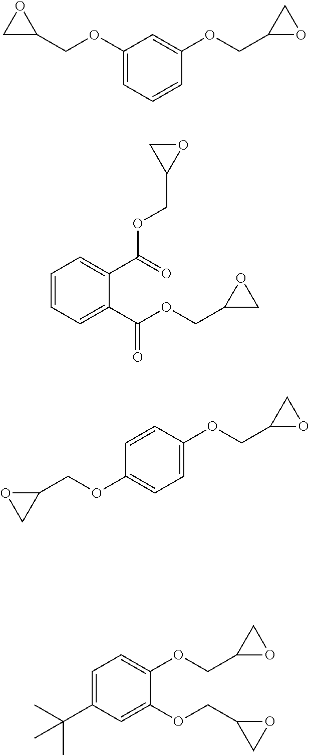

Examples of the copolymer having a repeating structural unit represented by the Formula (1-1) and a repeating structural unit represented by the following Formula (1-2) include copolymers having repeating structural units represented by the following Formulas (1a) to (1n).

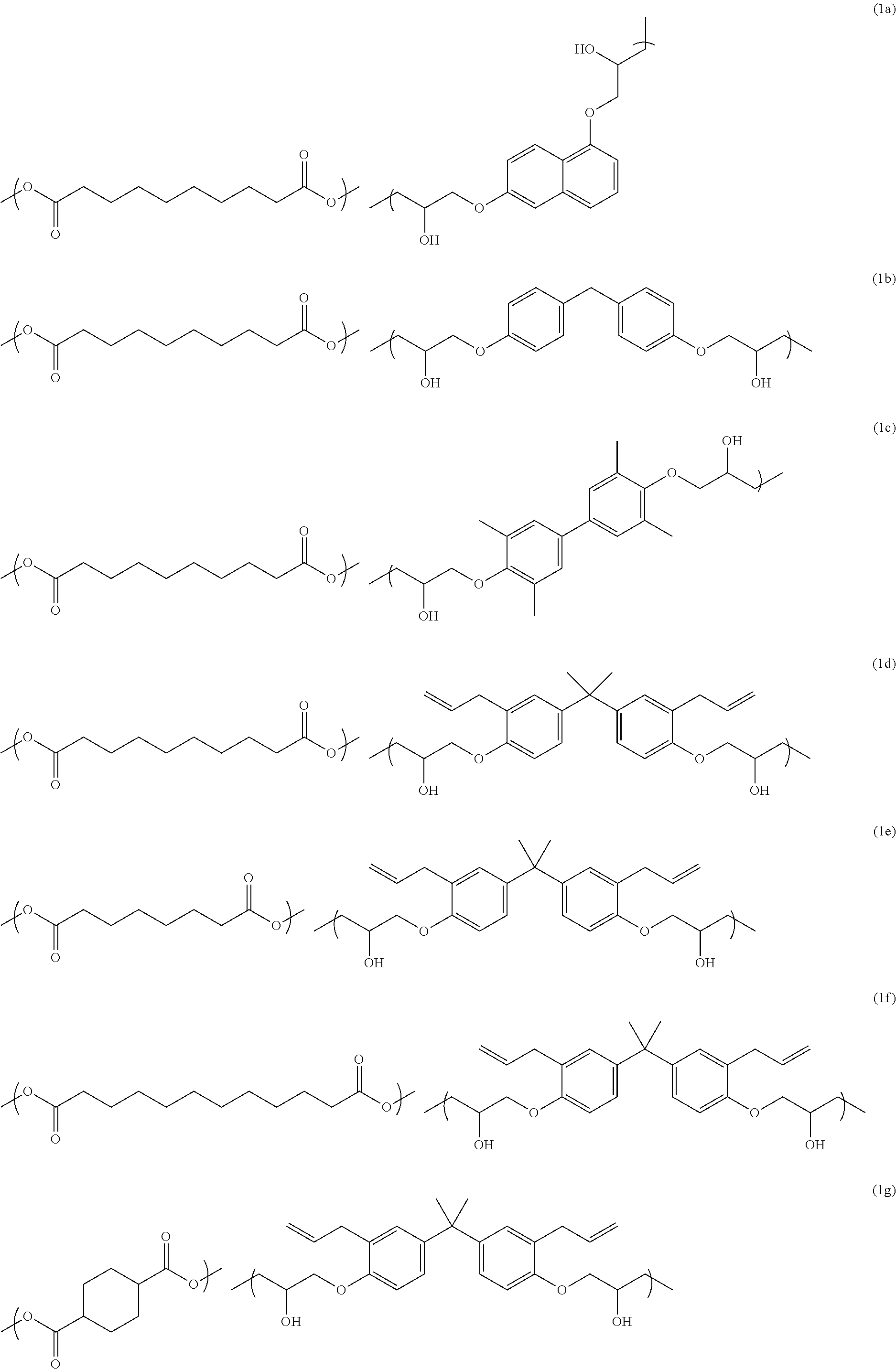

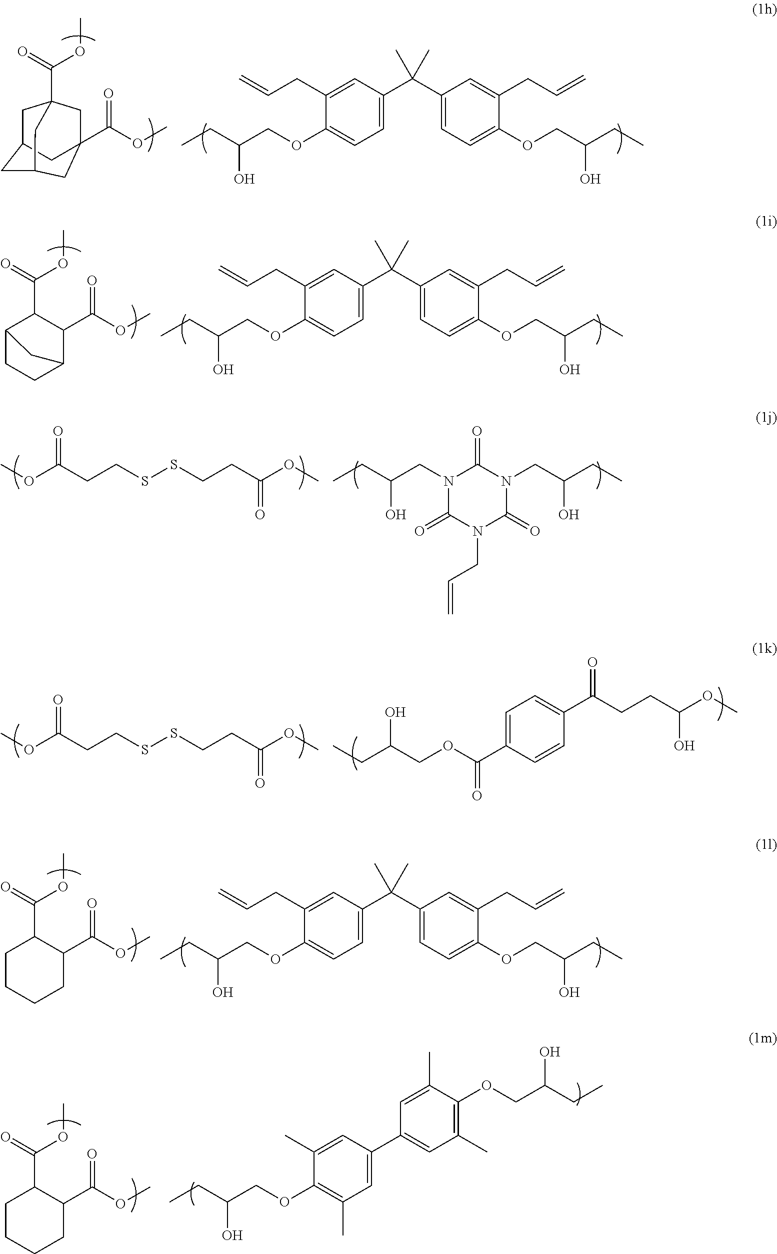

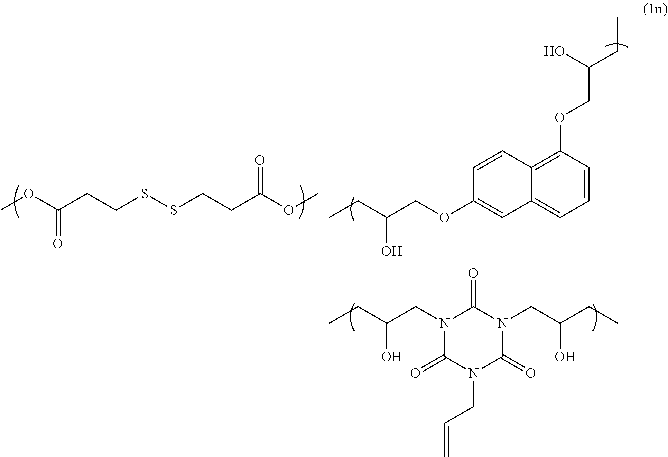

### Second Embodiment

A second embodiment is a compound or polymer (2A) containing a cyclic ether having a 3-membered ring structure or a 4-membered ring structure.

Examples of the compound or polymer (2A) are the following compound 2AA and polymer 2AB.

### <<<<Compound 2AA>>>>

An example of the compound or polymer (2A) is a compound (compound 2AA) having no repeating structural unit,
the compound containing a terminal group (A1), a multivalent group (A2), and a linking group (A3), wherein
the terminal group (A1) is bonded only to the linking group (A3),
the polyvalent group (A2) is bonded only to the linking group (A3), and
the linking group (A3) is bonded to the terminal group (A1) on one side and to the multivalent group (A2) on the other side, and may optionally be bonded to another linking group (A3),
the terminal group (A1) has any of the structures of the following Formula (I):

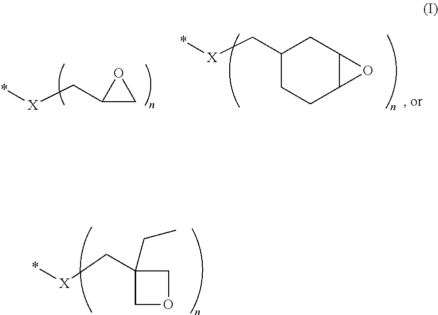

(wherein in Formula (I), * represents a binding site for the linking group (A3);
X represents an ether bond, an ester bond, or a nitrogen atom, and n=1 when X is an ether bond or an ester bond, while n=2 when X is a nitrogen atom),
the polyvalent group (A2) is a divalent to tetravalent group selected from the group consisting of:
—O—,
an aliphatic hydrocarbon group,
a combination of an aromatic hydrocarbon group having fewer than 10 carbon atoms and an aliphatic hydrocarbon group, and
a combination of an aromatic hydrocarbon group having 10 or more carbon atoms and —O—, and
the linking group (A3) represents an aromatic hydrocarbon group.

The phrase “having no repeating structural unit” means to exclude a so-called polymer having a repeating structural unit, such as a polyolefin, a polyester, a polyamide, or a poly(meth)acrylate. The weight average molecular weight of the compound (A) is preferably 300 or more and 1500 or less.

The “bond” between the terminal group (A1), the multivalent group (A2), and the linking group (A3) means a chemical bond, and this usually means a covalent bond but does not preclude an ionic bond.

The polyvalent group (A2) is a divalent to tetravalent group.

Therefore, the aliphatic hydrocarbon group in the definition of the multivalent group (A2) is a divalent to tetravalent aliphatic hydrocarbon group.

As non-limiting examples, examples of a divalent aliphatic hydrocarbon group include an alkylene group of a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, or an n-decanylene group.

When hydrogen at any site is removed from these groups, and the site is converted into a linking bond, trivalent and tetravalent groups are derived.

Examples of the aromatic hydrocarbon group having fewer than 10 carbon atoms in the definition of the polyvalent group (A2) include benzene, toluene, xylene, mesitylene, cumene, styrene, and indene.

Examples of the aliphatic hydrocarbon group that is combined with the aromatic hydrocarbon group having fewer than 10 carbon atoms include, in addition to the above-described alkylene groups, alkyl groups such as a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1 methyl-n-propyl group, a 1-ethyl-2 methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, and a decyl group.

Any of the aromatic hydrocarbon group having fewer than 10 carbon atoms and the aliphatic hydrocarbon group in the definition of the polyvalent group (A2) may be bonded to the linking group (A3).

Examples of the aromatic hydrocarbon group having 10 or more carbon atoms in the definition of the polyvalent group (A2) include naphthalene, azulene, anthracene, phenanthrene, naphthacene, triphenylene, pyrene, and chrysene.

It is preferable that the aromatic hydrocarbon group having 10 or more carbon atoms in the definition of the polyvalent group (A2) is bonded to the linking group (A3) through —O—.

Examples of the aromatic hydrocarbon group in the definition of the linking group (A3) include the above-described aromatic hydrocarbon group having fewer than 10 carbon atoms and the above-described aromatic hydrocarbon group having 10 or more carbon atoms.

Preferably, the compound 2AA has two or more linking groups (A3).

Preferably, the compound 2AA is represented by, for example, the following Formula (II):

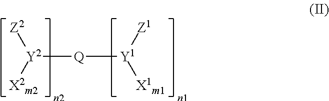

(wherein in Formula (II),
Z¹ and Z² each independently represent the following:

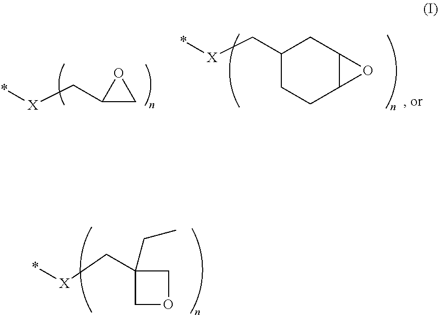

wherein in Formula (I), the symbol * represents a binding site for Y¹ or Y²,
X represents an ether bond, an ester bond, or a nitrogen atom, and n=1 when X is an ether bond or an ester bond, while n=2 when X is a nitrogen atom;
Y¹ and Y² each independently represent an aromatic hydrocarbon group;
X¹ and X² each independently represent —Y¹—Z¹ or —Y²—Z²;
n1 and n2 each independently represent an integer of 0 to 4, provided that either n1 or n2 is 1 or more;
m1 defined in (X¹)m1 represents 0 or 1;
m2 defined in (X²)m2 represents 0 or 1; and
Q represents a (n1+n2)-valent group selected from the group consisting of —O—, an aliphatic hydrocarbon group, a combination of an aromatic hydrocarbon group having fewer than 10 carbon atoms and an aliphatic hydrocarbon group, and a combination of an aromatic hydrocarbon group having 10 or more carbon atoms and —O—.)

It is preferable that Q is a divalent to tetravalent group.

In Formula (II), Z¹ and Z² correspond to the above-described terminal group (A1), Q corresponds to the above-described polyvalent group (A2), Y¹ and Y² correspond to the above-described linking group (A3), and the description, examples, and the like thereof are as described above.

The compound 2AA preferably contains, for example, a partial structure represented by the following Formula (III):

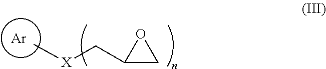

(wherein in Formula (III), Ar represents a benzene ring, a naphthalene ring, or an anthracene ring; and X represents an ether bond, an ester bond, or a nitrogen atom, and n=1 when X is an ether bond or an ester bond, while n=2 when X is a nitrogen atom.)

### <<<<Polymer (2AB)>>>>

Another example of the compound or polymer (2A) is a polymer (polymer 2AB) having a unit structure represented by the following Formula (1-1):

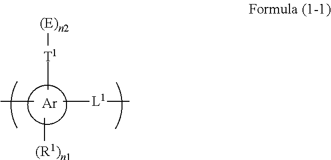

(wherein in Formula (1-1), Ar represents a benzene ring, a naphthalene ring, or an anthracene ring; R¹ represents a hydroxy group, a mercapto group which may be protected with a methyl group, an amino group which may be protected with a methyl group, a halogeno group, or an alkyl group having 1 to 10 carbon atoms which may be substituted with a hydroxy group which may be substituted with or interrupted by a heteroatom; n1 represents an integer of 0 to 3; L¹ represents a single bond or an alkylene group having 1 to 10 carbon atoms; n2 represents 1 or 2; E represents a group having an epoxy group, or a group having an oxetanyl group; and T¹ represents an alkylene group having 1 to 10 carbon atoms which may be interrupted by a single bond, an ether bond, an ester bond, or an amide bond when n2=1; and T¹ represents a nitrogen atom or an amide bond when n2=2.)

Examples of the alkyl group having 1 to 10 carbon atoms include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a decyl group, a methoxy group, an ethoxy group, a methoxymethyl group, an ethoxymethyl group, a methoxyethyl group, an ethoxyethyl group, a hydroxymethyl group, a 1-hydroxyethyl group, a 2-hydroxyethyl group, a methylamino group, a dimethylamino group, a diethylamino group, an aminomethyl group, a 1-aminoethyl group, a 2-aminoethyl group, a methylthio group, an ethylthio group, a mercaptomethyl group, a 1-mercaptoethyl group, and a 2-mercaptoethyl group.

Examples of the alkylene group having 1 to 10 carbon atoms include a methylene group, an ethylene group, an n-propylene group, an isopropylene group, a cyclopropylene group, an n-butylene group, an isobutylene group, an s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an n-octylene group, an n-nonylene group, and an n-decanylene group.

R¹ may be an alkoxy group having 1 to 10 carbon atoms.

Examples of the alkoxy group having 1 to 10 carbon atoms include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2,-trimethyl-n-propoxy group, a 1-ethyl-1-methyl-n-propoxy group, a 1-ethyl-2-methyl-n-propoxy group, an n-heptyloxy group, an n-octyloxy group, and an n-nonyloxy group.

The unit structure represented by Formula (1-1) may be one kind or a combination of two or more kinds. For example, the polymer (2AB) may be a copolymer having a plurality of unit structures in which Ar is of the same type, and for example, a copolymer having a plurality of unit structures in which the type of Ar is different, such as a copolymer having a unit structure in which Ar contains a benzene ring and a unit structure in which Ar has a naphthalene ring, is not excluded from the technical scope of the present application.

The phrase “may be interrupted” means that in the case of an alkylene group having 2 to 10 carbon atoms, any bond between carbon-carbon atoms in the alkylene group described on the left side is interrupted by a heteroatom (that is, an ether bond in the case of oxygen, and a sulfide bond in the case of sulfur), an ester bond, or an amide bond, and in a case where the number of carbon atoms is 1 (that is, a methylene group), the methylene group has a heteroatom (that is, an ether bond in the case of oxygen, and a sulfide bond in the case of sulfur), an ester bond, or an amide bond on any one side of the carbon of the methylene group.

T¹ represents an alkylene group having 1 to 10 carbon atoms which may be interrupted by a single bond, an ether bond, an ester bond, or an amide bond when n2=1; however, T¹ is preferably a combination of an ether bond and a methylene group (that is, when “-T¹-(E)n2” in Formula (1-1) is a glycidyl ether group), a combination of an ester bond and a methylene group, or a combination of an amide bond and a methylene group.

The alkyl group having 1 to 10 carbon atoms which may be substituted with a hetero atom means that one or more hydrogen atoms in the alkyl group having 1 to 10 carbon atoms are substituted with a hetero atom (preferably a halogeno group).

L¹ represents a single bond or an alkylene group having 1 to 10 carbon atoms; however, it is preferable that L¹ is represented by the following Formula (1-2):

—CR²R³— Formula (1-2)
(wherein in Formula (1-2), R² and R³ each independently represent a hydrogen atom, a methyl group, an ethyl group, an n-propyl group, an i-propyl group, a cyclopropyl group, an n-butyl group, an i-butyl group, an s-butyl group, a t-butyl group, or a cyclobutyl group, and R² and R³ may be bonded to each other to form a ring having 3 to 6 carbon atoms.) Among these, it is preferable that R² and R³ are both a hydrogen atom (that is, —(CR²R³)— is a methylene group).

The halogeno group refers to halogen-X (F, Cl, Br, I) substituted for hydrogen.

It is more preferable that E in Formula (1-1) is a group having an epoxy group.

Polymer 2AB is not particularly limited as long as it satisfies, for example, the unit structure of Formula (1-1). It may be produced by a known method. A commercially available product may also be used. Examples of the commercially available product include a heat-resistant epoxy novolac resin EOCN (registered trademark) series (manufactured by Nippon Kayaku Co., Ltd., and an epoxy novolac resin D.E.N (registered trademark) series (manufactured by Dow Chemical Japan, Ltd.).

The weight average molecular weight of the polymer 2AB is 100 or more, 500 to 200000, 600 to 50000, or 700 to 10000.

Examples of the polymer 2AB include polymers having the following unit structures.

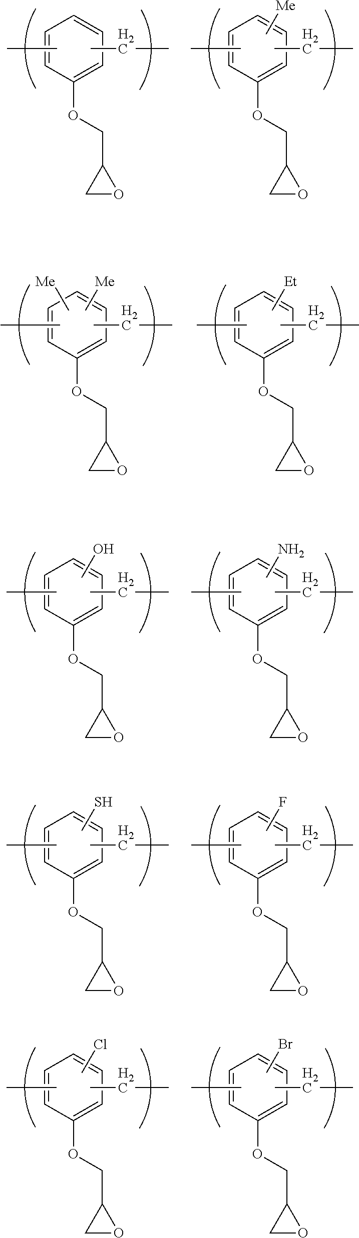

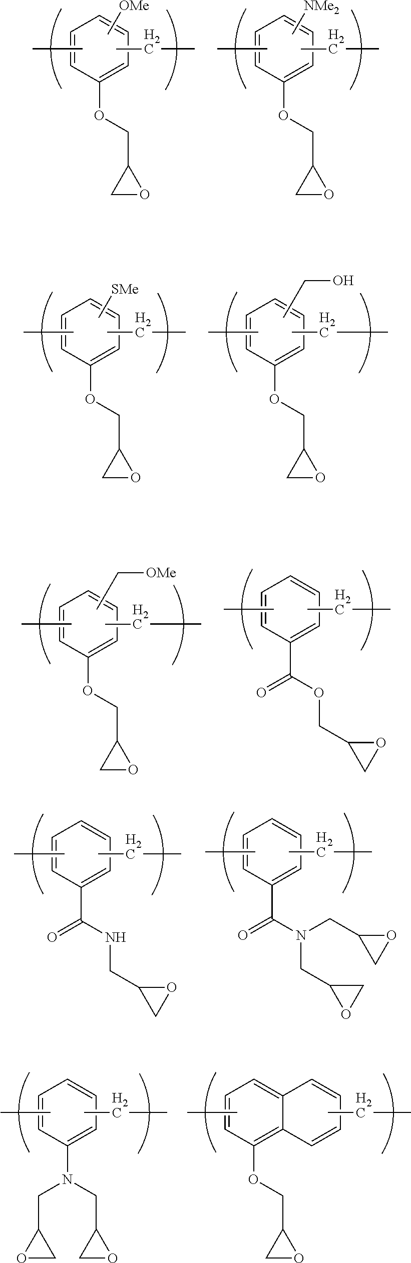

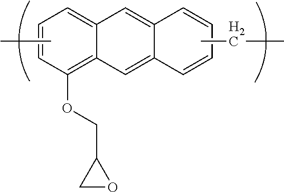

In the formulas, Me represents a methyl group, and Et represents an ethyl group.

### <<Solvent>>

The solvent used in the composition for forming a protective film is not particularly limited as long as it is a solvent capable of uniformly dissolving the contained components that are solid at normal temperature; however, generally, an organic solvent used in a chemical solution for a semiconductor lithography process is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used singly or in combination of two or more kinds thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <<Acid Generator>>

As a curing catalyst included as an optional component in the composition for forming a protective film, both a thermal acid generator and a photoacid generator can be used; however, it is preferable to use a thermal acid generator.

Examples of the thermal acid generator include sulfonic acid compounds and carboxylic acid compounds, such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (pyridinium p-phenolsulfonic acid salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoro-normal butanesulfonate, diphenyliodonium perfluoro-normal octanesulfonate, diphenyliodonium camphorsulfonate, bis(4-tert-butylphenyl) iodonium camphorsulfonate, and bis(4-tert-butylphenyl) iodonium trifluoromethanesulfonate; and sulfonium salt compounds such as triphenylsulfonium hexafluoroantimonate, triphenylsulfonium nonafluoro-normal butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro-normal butanesulfonyloxy)succinimide, N-(camphorsulfonyloxy)succinimide, and N-(trifluoromethanesulfonyloxy) naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

Only one kind of curing catalyst can be used, or two or more kinds thereof can be used in combination.

When a curing catalyst is used, the content proportion of the curing catalyst is, for example, 0.1% by mass to 50% by mass, and preferably 1% by mass to 30% by mass, with respect to the solid content.

### <<Other Components>>

In the composition for forming a protective film, a surfactant can be further added in order to prevent the generation of pinholes, striations, and the like and to further improve the coating property against surface unevenness. Examples of the surfactant include nonionic surfactants, such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octyl phenol ether and polyoxyethylene nonyl phenol ether; polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, EF352 (manufactured by TOCHEM PRODUCTS Co., Ltd., trade name), MEGAFACE F171, F173, R-30, and R-40 (manufactured by DIC Corporation, trade name), FLUORAD FC430 and FC431 (manufactured by Sumitomo 3M, Ltd., trade name), ASAHIGUARD AG710, and SURFLON S-382, SC101, SC102, SC103, SC104, SC105, and SC106 (manufactured by Asahi Glass Co., Ltd., trade name); and organosiloxane polymer KP341 (manufactured by Shin-Etsu Chemical Co., Ltd.). The blending amount of these surfactants is usually 2.0% by mass or less, and preferably 1.0% by mass or less, with respect to the total solid content of the composition for forming a protective film. These surfactants may be added alone, or may be added in combination of two or more kinds thereof.

The nonvolatile fraction included in the composition for forming a protective film, that is, the components excluding the solvent is, for example, 0.01% by mass to 10% by mass.

### (Method for Producing Resist Pattern-Attached Substrate and Method for Producing Semiconductor Device)

A method for producing a resist pattern-attached substrate according to the present invention includes the following steps (1) to (3):
step (1): a step of applying the composition for pretreatment of the present invention on a semiconductor substrate;
step (2): a step of applying the composition for forming a protective film on the semiconductor substrate on which the composition for pretreatment has been applied, and baking the composition to form a protective film; and
step (3): a step of forming a resist film directly on the protective film or with another layer interposed therebetween, and then exposing and developing the resist film to form a resist pattern.

A method for producing a semiconductor device according to the present invention includes the following steps (A) to (E):
treatment (A): a treatment of applying the composition for pretreatment of the present invention on a semiconductor substrate having an inorganic film formed on a surface thereof;
treatment (B): a treatment of forming a protective film on the semiconductor substrate on which the composition for pretreatment has been applied, using a composition for forming a protective film;
treatment (C): a treatment of forming a resist pattern directly on a protective film or with another layer interposed therebetween;
treatment (D): a treatment of subjecting the protective film to dry etching using the resist pattern as a mask to expose a surface of the inorganic film; and
treatment (E): a treatment of subjecting the inorganic film to wet etching by using the protective film after the dry etching as a mask and using a wet etching solution for semiconductors.

Examples of the semiconductor substrate on which the composition for pretreatment of the present invention is applied include a silicon wafer, a germanium wafer, and compound semiconductor wafers of gallium arsenide, indium phosphide, gallium nitride, indium nitride, and aluminum nitride.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a silicon oxynitride film, a boro-phospho silicate glass (BPSG) film, a titanium nitride film, a titanium oxynitride film, a tungsten nitride film, a gallium nitride film, and a gallium arsenide film.

The semiconductor substrate may be a step substrate in which so-called vias (holes), trenches (grooves), and the like are formed. For example, a via has a substantially circular shape when viewed from the top face, the diameter of the substantially circular shape is, for example, 2 nm to 20 nm while the depth is 50 nm to 500 nm, and the width of a trench (a recess on the substrate) is, for example, 2 nm to 20 nm while the depth is 50 nm to 500 nm.

Since the composition for forming a protective film of the present invention is such that the compounds included in the composition have small weight average molecular weights and small average particle sizes, the composition can fill in a step substrate such as described above, without defects such as voids (gap). It is an important characteristic that there are no defects such as voids for the subsequent steps of semiconductor production (wet etching/dry etching of the semiconductor substrate, resist pattern formation).

The composition for pretreatment of the present invention is applied on such a semiconductor substrate by an appropriate application method such as a spinner or a coater. After the application, the composition for forming a protective film may be applied without performing a heating treatment, or a heating treatment may be performed in order to remove the solvent. The heating temperature and the heating time in the case of performing the heating treatment are not particularly limited.

The composition for forming a protective film of the present invention is applied on the semiconductor substrate on which the composition for pretreatment has been applied, by an appropriate application method such as a spinner or a coater. Thereafter, a protective film is formed by performing baking using a heating unit such as a hot plate. The baking conditions are appropriately selected from a baking temperature of 100° C. to 400° C. and a baking time of 0.3 minutes to 60 minutes. It is preferable that the baking temperature is 120° C. to 350° C. while the baking time is 0.5 minutes to 30 minutes, and it is more preferable that the baking temperature is 150° C. to 300° C. while the baking time is 0.8 minutes to 10 minutes. The film thickness of the protective film to be formed is, for example, 0.001 μm to 10 μm, preferably 0.002 μm to 1 μm, and more preferably 0.005 μm to 0.5 μm. When the temperature at the time of baking is lower than the above-described range, crosslinking occurs insufficiently, and it may be difficult for the protective film to be formed to obtain resistance to a resist solvent or a basic aqueous solution of hydrogen peroxide. On the other hand, when the temperature at the time of baking is higher than the range, the protective film may be decomposed by heat.

A resist film is formed directly on the protective film formed as described above or with another layer interposed therebetween, and then the resist film is exposed and developed to form a resist pattern.

The exposure is performed through a mask (reticle) for forming a predetermined pattern, and for example, i-line, KrF excimer laser, ArF excimer laser, EUV (extreme ultraviolet radiation), or EB (electron beam) is used. An alkaline liquid developer is used for development, and a development temperature of 5° C. to 50° C. and a development time of 10 seconds to 300 seconds are used. As the alkaline liquid developer, for example, aqueous solutions of alkalis such as an inorganic alkali such as sodium hydroxide, potassium hydroxide, sodium carbonate, sodium silicate, sodium metasilicate, or ammonia water, a primary amine such as ethylamine or n-propylamine, a secondary amine such as diethylamine or di-n-butylamine, a tertiary amine such as triethylamine or methyldiethylamine, an alcoholamine such as dimethylethanolamine or triethanolamine, a quaternary ammonium salt such as tetramethylammonium hydroxide, tetraethylammonium hydroxide, or choline, and a cyclic amine such as pyrrole or piperidine, can be used. Furthermore, it is also possible to add an appropriate amount of an alcohol such as isopropyl alcohol, or a nonionic surfactant to the aqueous solutions of alkalis and use the mixtures. Among these, preferred liquid developers are quaternary ammonium salts, and more preferred are tetramethylammonium hydroxide and choline. In addition, a surfactant or the like can be added to these liquid developers. In place of the alkaline liquid developer, a method of performing development using an organic solvent such as butyl acetate, and developing a portion where the alkali dissolution rate of the photoresist is not improved, can also be used.

Next, the protective film is subjected to dry etching using the formed resist pattern as a mask. At that time, when the inorganic film is formed on a surface of the semiconductor substrate used, the surface of the inorganic film is exposed, and when the inorganic film is not formed on a surface of the semiconductor substrate used, the surface of the semiconductor substrate is exposed.

In addition, a desired pattern is formed by subjecting the protective film to wet etching using a wet etching solution for semiconductors by using the protective film after dry etching (when a resist pattern remains on the protective film, the resist pattern is also used) as a mask.

As the wet etching solution for semiconductors, a general chemical solution for etching a semiconductor wafer can be used, and for example, both a substance exhibiting acidity and a substance exhibiting basicity can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, phosphoric acid, and a mixed solution thereof.

Examples of the substance exhibiting basicity include basic hydrogen peroxide water obtained by mixing an organic amine such as ammonia, sodium hydroxide, potassium hydroxide, sodium cyanide, potassium cyanide, or triethanolamine with hydrogen peroxide water to make the pH basic. Specific examples thereof include SC-1 (ammonia-hydrogen peroxide solution). In addition to that, those capable of making the pH basic, for example, those which generate ammonia by mixing urea and hydrogen peroxide water and causing thermal decomposition of urea by heating, and finally make the pH basic, can also be used as chemical solutions for wet etching.

Among these, acidic hydrogen peroxide water or basic hydrogen peroxide water is preferable.

These chemical solutions may contain an additive such as a surfactant.

The use temperature of the wet etching solution for semiconductors is desirably 25° C. to 90° C., and more desirably 40° C. to 80° C. The wet etching time is desirably 0.5 minutes to 30 minutes, and more desirably 1 minute to 20 minutes.

### EXAMPLES

Next, the contents of the present invention will be specifically described by way of Examples; however, the present invention is not limited to these.

The weight average molecular weight of the polymer shown in the following examples is a measurement result obtained by gel permeation chromatography (hereinafter, abbreviated as GPC). For the measurement, a GPC apparatus manufactured by Tosoh Corporation was used, and measurement conditions and the like are as follows.
Column temperature: 40
Flow rate: 0.35 ml/min
Eluent: tetrahydrofuran (THF)
Standard sample: polystyrene (Tosoh Corporation)

### Preparation Example 1

To 30.53 g of a propylene glycol monomethyl ether acetate solution (solid content was 16.4% by mass) of a reaction product (a copolymer corresponding to the following Formula (1n) and having a weight average molecular weight of 4500 as measured by GPC and calculated relative to polystyrene standards) obtained by the method described in Synthesis Example 12 of WO 2020/026834, 0.18 g of pyridinium trifluoromethanesulfonic acid (manufactured by Tokyo Chemical Industry Co., Ltd.), 0.01 g of a surfactant (product name: MEGAFACE R-40, manufactured by DIC Corporation), 59.79 g of propylene glycol monomethyl ether, and 9.48 g of propylene glycol monomethyl ether acetate were added, and a solution was prepared. The solution was filtered using a polyethylene microfilter having a pore size of 0.02 μm to prepare a composition for forming a protective film.

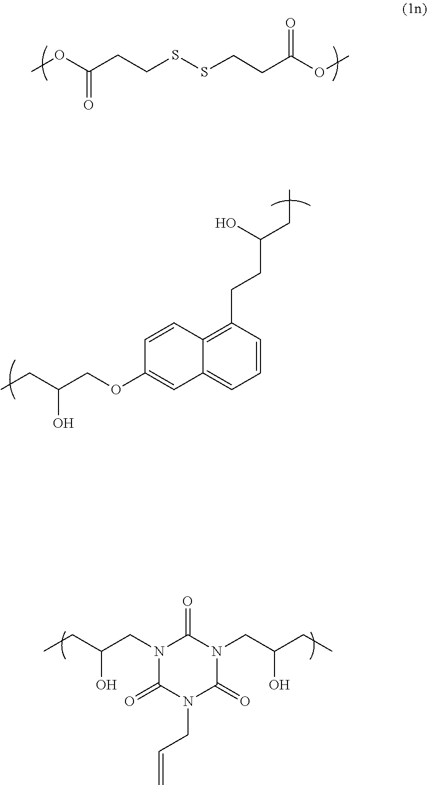

### Preparation Example 2

To 26.21 g of a propylene glycol monomethyl ether acetate solution (solid content was 20.0% by mass) of epoxy novolac resin EOCN-104S (manufactured by Nippon Kayaku Co., Ltd., a copolymer corresponding to the following Formula (1m) and having a weight average molecular weight of 3100 as measured by GPC and calculated relative to polystyrene standards), 0.05 g of an acid generator (K-PURE [registered trademark] TAG-2689, manufactured by King Industries, Inc.), 0.01 g of a surfactant (product name: MEGAFACE R-40, manufactured by DIC Corporation), 28.41 g of propylene glycol monomethyl ether, and 45.32 g of propylene glycol monomethyl ether acetate were added, and a solution was prepared. The solution was filtered using a polyethylene microfilter having a pore size of 0.02 μm to prepare a composition for forming a protective film.

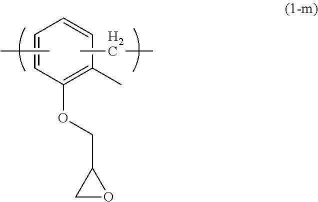

### Preparation Example 3

To 27.44 g of a propylene glycol monomethyl ether acetate solution (solid content was 16.4% by mass) of a reaction product (a copolymer corresponding to the above-described Formula (1n) and having a weight average molecular weight of 4500 as measured by GPC and calculated relative to polystyrene standards) obtained by the method described in Synthesis Example 12 of WO 2020/026834, 0.18 g of pyridinium trifluoromethanesulfonic acid (manufactured by Tokyo Chemical Industry Co., Ltd.), 0.22 g of gallic acid, 0.01 g of a surfactant (product name: MEGAFACE R-40, manufactured by DIC Corporation), 62.68 g of propylene glycol monomethyl ether, and 9.51 g of propylene glycol monomethyl ether acetate were added, and a solution was prepared. The solution was filtered using a polyethylene microfilter having a pore size of 0.02 μm to prepare a composition for forming a protective film.

### Example 1

A propylene glycol monomethyl ether solution (solid content was 1.0% by mass) of gallic acid was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 2

A propylene glycol monomethyl ether solution (solid content was 1.0% by mass) of tannic acid (manufactured by FUJIFILM Wako Pure Chemical Corporation) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 3

A propylene glycol monomethyl ether solution (solid content was 1.0% by mass) of 3,4-dihydroxybenzoic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 4

A propylene glycol monomethyl ether solution (solid content was 1.0% by mass) of 2,4-dihydroxybenzoic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 5

A propylene glycol monomethyl ether solution (solid content was 1.0% by mass) of 3-hydroxybenzoic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 6

A propylene glycol monomethyl ether solution (solid content was 1.0% by mass) of methyl gallate (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 7

A propylene glycol monomethyl ether solution (solid content was 1.0% by mass) of butyl gallate (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 8

A propylene glycol monomethyl ether solution (solid content was 1.0% by mass) of caffeic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 9

A propylene glycol monomethyl ether solution (solid content was 1.0% by mass) of dihydrocaffeic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 10

A propylene glycol monomethyl ether solution (solid content was 1.0% by mass) of syringic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 11

A propylene glycol monomethyl ether solution (solid content was 1.0% by mass) of pyrogallol (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 12

An aqueous solution (solid content was 1.0% by mass) of L-ascorbic acid (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 13

An aqueous solution (solid content was 1.0% by mass) of bisdemethoxycurcumin (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 14

An aqueous solution (solid content was 1.0% by mass) of 5,5′-dimethyl-2,2′-bipyridyl (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 15

An aqueous solution (solid content was 1.0% by mass) of pyridine-2-carboxylic acid (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 16

An aqueous solution (solid content was 1.0% by mass) of pyromellitic acid (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 1 was applied thereon and heated at 220° C. for 1 minute to form a protective film (film thickness was 150 nm).

### Example 17

A propylene glycol monomethyl ether solution (solid content was 1.0% by mass) of gallic acid was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 18

A propylene glycol monomethyl ether solution (solid content was 1.0% by mass) of methyl gallate (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 19

A propylene glycol monomethyl ether solution (solid content was 1.0% by mass) of butyl gallate (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 20

A propylene glycol monomethyl ether solution (solid content was 1.0% by mass) of tannic acid (manufactured by FUJIFILM Wako Pure Chemical Corporation) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 21

A propylene glycol monomethyl ether solution (solid content was 1.0% by mass) of syringic acid (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 22

A propylene glycol monomethyl ether solution (solid content was 1.0% by mass) of pyrogallol (manufactured by Tokyo Chemical Industry Co., Ltd.) was filtered using a polyethylene microfilter having a pore size of 0.02 μm. The solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 23

An aqueous solution (solid content was 1.0% by mass) of bisdemethoxycurcumin (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 24

An aqueous solution (solid content was 1.0% by mass) of 5,5′-dimethyl-2,2′-bipyridyl (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 25

An aqueous solution (solid content was 1.0% by mass) of 4-carboxyphenylboronic acid (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Example 26

An aqueous solution (solid content was 1.0% by mass) of leucoquinizarin (manufactured by Tokyo Chemical Industry Co., Ltd.) was filtered using a polyethylene microfilter having a pore size of 0.02 μm. The aqueous solution after filtration was applied on a titanium nitride (TiN) vapor deposited film-attached substrate (film thickness of the TiN vapor deposited film was 50 nm), and then the composition for forming a protective film of Preparation Example 2 was applied thereon and heated at 220° C. for 1 minute to form a protective film (film thickness was 150 nm).

### Comparative Example 1

The composition for forming a protective film prepared in Preparation Example 1 was applied on a titanium nitride (TiN) vapor deposited film-attached substrate (film thickness of the TiN vapor deposited film was 50 nm) and heated at 220° C. for 1 minute to form a protective film such that the film thickness was 150 nm.

### Comparative Example 2

The composition for forming a protective film prepared in Preparation Example 2 was applied on a titanium nitride (TiN) vapor deposited film-attached substrate (film thickness of the TiN vapor deposited film was 50 nm) and heated at 220° C. for 1 minute to form a protective film such that the film thickness was 150 nm.

### Comparative Example 3

The composition for forming a protective film prepared in Preparation Example 3 was applied on a titanium nitride (TiN) vapor deposited film-attached substrate (film thickness of the TiN vapor deposited film was 50 nm) and heated at 220° C. for 1 minute to form a protective film such that the film thickness was 150 nm.

### [Test for Resistance to Basic Hydrogen Peroxide Water]

As an evaluation of resistance to basic hydrogen peroxide water, 28% by mass ammonia water, 33% by mass hydrogen peroxide water, and water were mixed at a mass ratio (ammonia water:hydrogen peroxide water:water) of 1:4:20, and basic hydrogen peroxide water was prepared. Next, the TiN vapor deposited film-attached substrates on which a protective film was formed in Example 1 to Example 26 and Comparative Example 1 and Comparative Example 2 were immersed in basic hydrogen peroxide water heated to 70° C., and the time (peeling time) taken from immediately after immersion until the protective film was completely peeled off from the substrate, was measured. The results of the test for the resistance to basic hydrogen peroxide water are shown in Tables 1 and 2 (relative values when the peeling time of each Comparative Example was converted to 1.00). Thus, it can be said that as the peeling time is longer, the resistance to a wet etching solution using the basic hydrogen peroxide water is higher.

The results of the resistance test for the protective film formed from the composition for forming a protective film obtained in Preparation Example 1 are shown in Table 1.

The results of the test for resistance to the protective film formed from the composition for forming a protective film obtained in Preparation Example 2 are shown in Table 2.

TABLE 1

| | | Resistance time of |
|---|---|---|
| | | protective film |
| | | (calculated relative to |
| | | resistance time of |
| | | Comparative Example 1 |
| | Compound | taken as 1.00) |
| Example 1 | Gallic acid | 3.30 |
| Example 2 | Tannic acid | 2.26 |
| Example 3 | 3,4-Dihydroxybenzoic acid | 2.10 |
| Example 4 | 2,4-Dihydroxybenzoic acid | 1.60 |
| Example 5 | 3-Hydroxybenzoic acid | 1.20 |
| Example 6 | Methyl gallate | 1.76 |
| Example 7 | Butyl gallate | 1.12 |
| Example 8 | Caffeic acid | 1.17 |
| Example 9 | Dihydrocaffeic acid | 1.17 |
| Example 10 | Syringic acid | 1.06 |
| Example 11 | Pyrogallol | 1.12 |
| Example 12 | L-ascorbic acid | 1.96 |
| Example 13 | Bisdemethoxycurcumin | 1.57 |
| Example 14 | 5,5′-Dimethyl-2,2′- | 1.94 |
| | bipyridyl | |
| Example 15 | Pyridine-2-carboxylic acid | 1.37 |
| Example 16 | Pyromellitic acid | 1.18 |
| Comparative | — | 1.00 |
| Example 1 | | |

TABLE 2

| | | Resistance time of |
|---|---|---|
| | | protective film |
| | | (calculated relative to |
| | | resistance time of |
| | | Comparative Example 2 |
| | Compound | taken as 1.00) |
| Example 17 | Gallic acid | 3.00 |
| Example 18 | Methyl gallate | 1.99 |
| Example 19 | Butyl gallate | 1.41 |
| Example 20 | Tannic acid | 1.38 |
| Example 21 | Syringic acid | 1.15 |
| Example 22 | Pyrogallol | 1.64 |
| Example 23 | Bisdemethoxycurcumin | 2.05 |
| Example 24 | 5,5′-Dimethyl-2,2′- | 1.44 |
| | bipyridyl | |
| Example 25 | 4-Carboxyphenylboronic | 1.31 |
| | acid | |
| Example 26 | Leucoquinizarin | 1.28 |
| Comparative | — | 1.00 |
| Example 2 | | |

The structures of the compounds used in Examples are shown below.

### Gallic Acid (the Following Structural Formula)

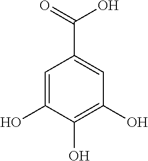 [SMILES: O=C(O)c1cc(O)c(O)c(O)c1]

### Tannic Acid (the Following Structural Formula)

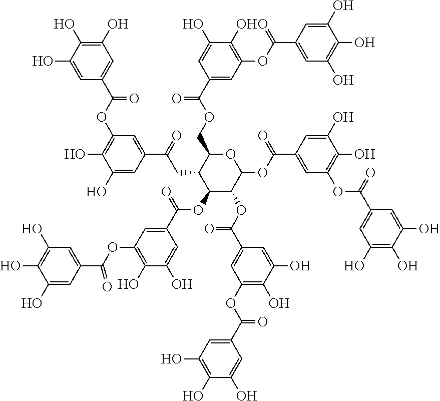 [SMILES: O=C(C[C@H]1[C@H](OC(=O)c2cc(O)c(O)c(OC(=O)c3cc(O)c(O)c(O)c3)c2)[C@@H](OC(=O)c2cc(O)c(O)c(OC(=O)c3cc(O)c(O)c(O)c3)c2)C(OC(=O)c2cc(O)c(O)c(OC(=O)c3cc(O)c(O)c(O)c3)c2)O[C@@H]1COC(=O)c1cc(O)c(O)c(OC(=O)c2cc(O)c(O)c(O)c2)c1)c1cc(O)c(O)c(OC(=O)c2cc(O)c(O)c(O)c2)c1]

### 3,4-Dihydroxybenzoic Acid (the Following Structural Formula)

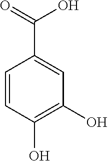 [SMILES: O=C(O)c1ccc(O)c(O)c1]

### 2,4-Dihydroxybenzoic Acid (the Following Structural Formula)

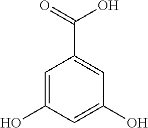 [SMILES: O=C(O)c1cc(O)cc(O)c1]

### 3-Hydroxybenzoic Acid (the Following Structural Formula)

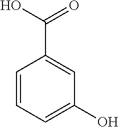

### Methyl Gallate (the Following Structural Formula)

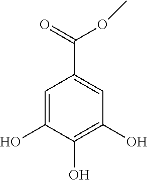

### Butyl Gallate (the Following Structural Formula)

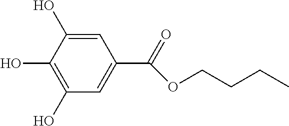 [SMILES: CCCCOC(=O)c1cc(O)c(O)c(O)c1]

### Caffeic Acid (the Following Structural Formula)

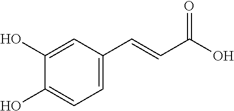 [SMILES: O=C(O)/C=C/c1ccc(O)c(O)c1]

### Dihydrocaffeic Acid (the Following Structural Formula)

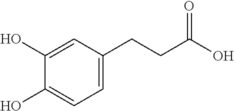 [SMILES: O=C(O)CCc1ccc(O)c(O)c1]

### Syringic Acid (the Following Structural Formula)

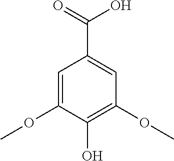

### Pyrogallol (the Following Structural Formula)

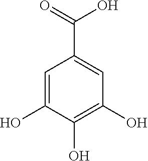 [SMILES: O=C(O)c1cc(O)c(O)c(O)c1]

### L-Ascorbic Acid (the Following Structural Formula)

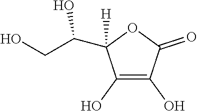 [SMILES: O=C1O[C@H]([C@@H](O)CO)C(O)=C1O]

### Bisdemethoxycurcumin (the Following Structural Formula)

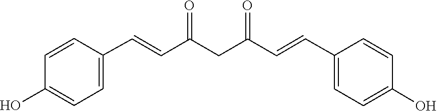 [SMILES: O=C(/C=C/c1ccc(O)cc1)CC(=O)/C=C/c1ccc(O)cc1]

### 5,5′-Dimethyl-2,2′-Bipyridyl (the Following Structural Formula)

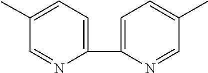

### Pyridine-2-Carboxylic Acid (the Following Structural Formula)

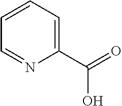

### Pyromellitic Acid (the Following Structural Formula)

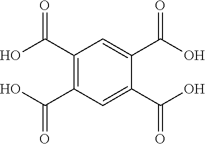 [SMILES: O=C(O)c1cc(C(=O)O)c(C(=O)O)cc1C(=O)O]

### 4-Carboxyphenylboronic Acid (the Following Structural Formula)

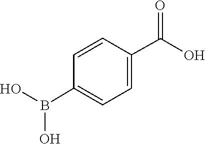 [SMILES: O=C(O)c1ccc(B(O)O)cc1]

### Leucoquinizarin (the Following Structural Formula)

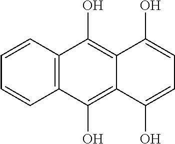 [SMILES: Oc1ccc(O)c2c(O)c3ccccc3c(O)c12]

### [Measurement of Sublimate Quantity]

Measurement of the sublimate quantity was performed using a sublimate quantity measuring apparatus described in WO 2007/111147 A.

First, a propylene glycol monomethyl ether solution of gallic acid (solid content was 1.0% by mass, the solution was filtered using a polyethylene microfilter having a pore size of 0.02 μm) was applied on a silicon wafer substrate having a diameter of 4 inches using a spin coater, and then the composition for forming a protective film of Preparation Example 1 was applied thereon such that the film thickness of a protective film to be obtained would be 150 nm (since this corresponds to Example 1, hereinafter will be referred to as Example 1).

On the other hand, the composition for forming a protective film prepared in Preparation Example 1 was applied on a silicon wafer substrate having a diameter of 4 inches such that the film thickness of a protective film to be obtained would be 150 nm (since this corresponds to Comparative Example 1, will be referred to as Comparative Example 1).

On the other hand, the composition for forming a protective film prepared in Preparation Example 3 was applied on a silicon wafer substrate having a diameter of 4 inches such that the film thickness of a protective film to be obtained would be 150 nm (since this corresponds to Comparative Example 3, will be referred to as Comparative Example 3).

Each of the wafers on which a composition for forming a protective film was applied was placed in the sublimate quantity measuring apparatus integrated with a hot plate and baked for 60 seconds, and the sublimate was collected on a Quartz Crystal Microbalance (QCM) sensor, that is, a crystal oscillator on which an electrode was formed. A QCM sensor can measure a small amount of mass change by utilizing a property that when a sublimate adheres to the surface (electrode) of the crystal oscillator, the frequency of the crystal oscillator changes (decreases) in accordance with the mass of the sublimate.

The detailed measurement procedure is as follows. The temperature of the hot plate of the sublimate quantity measuring apparatus was raised to the measurement temperature (baking temperature) described in Table 3, the pump flow rate was set to 2.4 m³/s, and the apparatus was left to stand for the first 60 seconds for stabilization of the apparatus. Immediately thereafter, the wafer coated with the composition for forming a protective film was rapidly placed on the hot plate through a slide port, and the sublimate was collected from the time point of 60 seconds to the time point of 120 seconds (for 60 seconds). The flow attachment (detection portion) serving as a connection between the QCM sensor and the collection funnel portion of the sublimate quantity measuring apparatus is used without attaching a nozzle thereto, and therefore, an air stream flows in through a flow path (diameter: 32 mm) of a chamber unit having a distance from the sensor (crystal oscillator) of 30 mm, without being narrowed. For the QCM sensor, a material containing silicon and aluminum as main components (AlSi) was used as an electrode, a sensor in which the diameter (sensor diameter) of the crystal oscillator was 14 mm, the electrode diameter on the surface of the crystal oscillator was 5 mm, and the resonance frequency was 9 MHz, was used.

The obtained frequency change was converted from the eigenvalue of the crystal oscillator used for measurement to grams, and the relationship between the sublimate quantity of one wafer on which the composition for forming a protective film was applied and the lapse of time was clarified. The first 60 seconds are a time zone during which the wafer was left to stand for apparatus stabilization (no wafer was placed), and the measurement value from the time point of 60 seconds when the wafer was placed on the hot plate to the time point of 120 seconds is the measurement value related to the sublimate quantity of the wafer. The sublimate quantity of the protective film quantified from the apparatus is shown in Table 3 as a sublimate quantity ratio. Further, the sublimate quantity is shown as a relative value calculated relative to the value of Comparative Example 3 taken as 1.00.

TABLE 3

| | | Sublimate quantity |
|---|---|---|
| | | (calculated relative to |
| | | amount of Comparative |
| | Baking temperature | Example 3 taken as 1.00) |
| Example 1 | 220° C. | 0.66 |
| Comparative | 220° C. | 0.66 |
| Example 1 | | |
| Comparative | 220° C. | 1.00 |
| Example 3 | | |

1. A composition for pretreatment to be applied on a semiconductor substrate before a protective film is formed on the semiconductor substrate using a composition for forming a protective film,
the composition for pretreatment comprising: at least one compound (A) selected from a compound having an aromatic ring and an aromatic hydroxy group, an organic reducing agent, and a chelating agent; and a solvent (B).

2. The composition for pretreatment according to claim 1, wherein the compound having an aromatic ring and an aromatic hydroxy group is at least one selected from tannic acid and a compound represented by the following Formula (1): 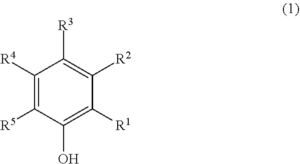
in Formula (1), R¹ to R⁵ each independently represent a hydrogen atom, a hydroxy group, an alkoxy group having 1 to 3 carbon atoms, a carboxy group, an alkyloxycarbonyl group, or a carboxyl hydrocarbon group;
provided that at least one of R¹ to R⁵ represents a hydroxy group, an alkoxy group having 1 to 3 carbon atoms, a carboxy group, an alkyloxycarbonyl group, or a carboxy hydrocarbon group.

3. The composition for pretreatment according to claim 1, wherein the organic reducing agent is at least one selected from ascorbic acid and an ascorbic acid derivative.

4. The composition for pretreatment according to claim 1, wherein
the chelating agent has a first partial structure selected from a pyridine ring, an aromatic hydroxy group, and an acid group, and a second partial structure selected from a pyridine ring, an aromatic hydroxy group, and an acid group, or
the chelating agent has a β-diketone structure (—C(═O)—CH₂—C(═O)—).

5. The composition for pretreatment according to claim 4, wherein
the acid group in the first partial structure is either a carboxyl group (—COOH) directly linked to an aromatic ring, or a dihydroxyboryl group (—B(OH)₂) directly linked to an aromatic ring, and
the acid group in the second partial structure is either a carboxyl group (—COOH) directly linked to an aromatic ring, or a dihydroxyboryl group (—B(OH)₂) directly linked to an aromatic ring.

6. The composition for pretreatment according to claim 1, wherein the solvent (B) includes at least one selected from water and a glycol-based solvent.

7. The composition for pretreatment according to claim 1, wherein
a content of the compound (A) is 0.1% by mass to 10% by mass, and
a content of the solvent (B) is 90% by mass to 99.9% by mass.

8. A method for producing a resist pattern-attached substrate used in semiconductor production, the method comprising:
a step of applying the composition for pretreatment according to claim 1 on a semiconductor substrate;
a step of applying a composition for forming a protective film on the semiconductor substrate on which the composition for pretreatment has been applied, and baking the composition for forming a protective film to form a protective film; and
a step of forming a resist film directly on the protective film or with another layer interposed therebetween, and then exposing and developing the resist film to form a resist pattern.

9. A method for producing a semiconductor device, the method comprising steps of: applying the composition for pretreatment according to claim 1 on a semiconductor substrate having an inorganic film formed on a surface thereof; forming a protective film on the semiconductor substrate on which the composition for pretreatment has been applied, using a composition for forming a protective film; forming a resist pattern directly on the protective film or with another layer interposed therebetween; subjecting the protective film to dry etching using the resist pattern as a mask to expose a surface of the inorganic film; and subjecting the inorganic film to wet etching by using the protective film after the dry etching as a mask and using a wet etching solution for semiconductors.
